(19) United States
(12) Patent Application Publication
(10) Pub. No.: US 2025/0274066 A1
(43) Pub. Date: Aug. 28, 2025

(54) METHOD OF DETERMINING STATE OF MOTOR AND DRIVING MODULE FOR PERFORMING THE METHOD

(71) Applicant: Samsung Electronics Co., Ltd., Suwon-si (KR)

(72) Inventors: Dooyoung YANG, Suwon-si (KR); Hongkwon KIM, Suwon-si (KR); Yongjae SONG, Suwon-si (KR); Sanghoon JUNG, Suwon-si (KR)

(21) Appl. No.: 19/059,101

(22) Filed: Feb. 20, 2025

Related U.S. Application Data
(63) Continuation of application No. PCT/KR2024/021155, filed on Dec. 26, 2024.

(30) Foreign Application Priority Data
Feb. 28, 2024 (KR) 10-2024-0029132

(51) Int. Cl. H02P 21/00; A61H 1/02; A61H 3/00; G01R 33/07; H02P 21/14

(52) U.S. Cl. CPC H02P 21/0017; A61H 1/0244; A61H 3/00; G01R 33/072; H02P 21/14; A61H 2201/0157; A61H 2201/1652; A61H 2201/5069

(57) ABSTRACT

A method of determining a state of a motor in a wearable device, such as a walking assist device, may include controlling the motor such that a shaft of the motor rotates at a target speed, receiving a first sensing signal from a first Hall sensor configured to sense a rotation angle of the shaft of the motor, and receiving a second sensing signal from a second Hall sensor, while the shaft of the motor rotates at the target speed, and determining whether the first Hall sensor and the second Hall sensor are arranged normally within the motor based on the first sensing signal and the second sensing signal.

### CROSS-REFERENCE TO RELATED APPLICATIONS

This application is a continuation application of International Application No. PCT/KR2024/021155 designating the United States, filed on Dec. 26, 2024, in the Korean Intellectual Property Receiving Office and claiming priority to Korean Patent Application No. 10-2024-0029132, filed on Feb. 28, 2024, in the Korean Intellectual Property Office, the disclosures of which are all hereby incorporated by reference herein in their entireties.

### BACKGROUND

### 1. Field

Certain example embodiments relate to technology involving determining a state of a motor, and for example, to determining a state of a motor including a plurality of Hall sensors.

### 2. Description of Related Art

A change into aging societies has contributed to a growing number of people who experience inconvenience and pain from reduced muscular strength or joint problems due to aging. Thus, there is a growing interest in walking assist devices that enable elderly users or patients/persons with reduced muscular strength or joint problems to walk with less effort and/or to exercise.

### SUMMARY

According to an example embodiment, a driving module may include at least one processor comprising processing circuitry, and memory storing instructions executable by the at least one processor, wherein the instructions, when executed by the at least one processor, cause the driving module to at least: control a motor of the driving module such that a shaft of the motor rotates at a target speed; receive a first sensing signal from a first Hall sensor and receive a second sensing signal from a second Hall sensor, while the shaft of the motor rotates at the target speed, the first Hall sensor being configured to sense a rotation angle of the shaft of the motor; and determine whether the first Hall sensor and the second Hall sensor are arranged normally within the motor, based on the first sensing signal and the second sensing signal.

According to an example embodiment, a method of determining a state of a motor, performed by a driving module, may include controlling a motor of the driving module such that a shaft of the motor rotates at a target speed; receiving a first sensing signal from a first Hall sensor and receiving a second sensing signal from a second Hall sensor, while the shaft of the motor rotates at the target speed, the first Hall sensor being configured to sense a rotation angle of the shaft of the motor; and determining whether the first Hall sensor and the second Hall sensor are arranged normally within the motor, based on the first sensing signal and the second sensing signal.

According to an example embodiment, a wearable device may include a base body configured to be disposed on, directly or indirectly, an area of a lower back of a user when the wearable device is worn on a body of the user, a waist support frame and a leg support frame configured to support at least a part of the body of the user, a thigh fastening portion configured to operatively associate (e.g., fix) the leg support frame to/with a thigh(s) of the user, an inertial measurement unit (IMU), comprising a sensor and/or circuitry, disposed within the base body, and a driving module configured to generate a torque applied to a leg of the user, the driving module being disposed between the waist support frame and the leg support frame and including at least one processor comprising processing circuitry, memory storing instructions executable by the processor, a motor, and a first Hall sensor and a second Hall sensor configured to sense a rotation angle of a shaft of the motor, and a control module configured to control the wearable device, wherein the instructions, when executed by the processor, are configured to cause the driving module to at least obtain an output current trajectory used to control the motor which appears based on a command current trajectory used to control the motor, and determine whether the first Hall sensor and the second Hall sensor are arranged normally within the motor based on the command current trajectory and the output current trajectory.

### BRIEF DESCRIPTION OF THE DRAWINGS

The above and other aspects, features, and advantages of certain example embodiments of the present disclosure will be more apparent from the following detailed description, taken in conjunction with the accompanying drawings, in which:

FIG. 1 is a diagram illustrating an overview of a wearable device worn on a body of a user, according to an example embodiment;

FIG. 2 is a diagram illustrating an exercise management system including a wearable device and an electronic device, according to an example embodiment;

FIG. 3 is a rear schematic view of a wearable device, according to an example embodiment;

FIG. 4 is a left side view of a wearable device, according to an example embodiment;

FIGS. 5A and 5B are diagrams illustrating a configuration of a control system of a wearable device, according to an example embodiment;

FIG. 5C is a diagram illustrating a configuration of a driving module according to an example embodiment;

FIG. 6 is a diagram illustrating an interaction between a wearable device and an electronic device, according to an example embodiment;

FIG. 7 is a diagram illustrating a configuration of an electronic device, according to an example embodiment;

FIG. 8 illustrates a motor and motor driver circuit, according to an example embodiment;

FIG. 9A illustrates a magnet with a changing rotation angle and a plurality of Hall sensors arranged around the magnet, according to an example embodiment;

FIG. 9B illustrates a plurality of sensing signals of a plurality of Hall sensors sensed for a rotation of a magnet, according to an example embodiment;

FIG. 9C illustrates a first rotation angle trajectory of a magnet determined based on a plurality of sensing signals of a plurality of Hall sensors and a linear second rotation angle trajectory determined based on the first rotation angle trajectory, according to an example embodiment;

FIG. 9D illustrates a torque trajectory that appears as currents applied to a motor are controlled in six steps, according to an example embodiment;

FIG. 10 illustrates a torque trajectory that appears as currents applied to a motor are controlled by field-oriented control (FOC), according to an example embodiment;

FIG. 11 is a flowchart of a method of determining a state of a motor, according to an example embodiment;

FIG. 12 is a flowchart of a method of determining whether Hall sensors are arranged normally within a motor based on a rotation timing chart for a shaft of the motor generated using sensing signals, according to an example embodiment;

FIG. 13A is a flowchart of a method of determining that Hall sensors are arranged normally within a motor based on a rotation timing chart for a shaft of the motor generated using sensing signals, according to an example embodiment;

FIG. 13B illustrates a rotation timing chart for a shaft of a motor generated using sensing signals, according to an example embodiment;

FIG. 13C illustrates rotation angles of a shaft of a motor for each section, according to an example embodiment;

FIG. 14A is a flowchart of a method of determining that Hall sensors are arranged abnormally within a motor based on a rotation timing chart for a shaft of the motor generated using sensing signals, according to an example embodiment;

FIG. 14B illustrates a rotation timing chart for a shaft of a motor generated using sensing signals, according to an example embodiment;

FIG. 14C illustrates rotation angles of a shaft of a motor for each section, according to an example embodiment;

FIG. 15 illustrates a rotation timing chart for a shaft of a motor with calibrated reference sections, according to an example embodiment;

FIG. 16 illustrates a trajectory of a rotation angle of a shaft of a motor determined using calibrated reference sections, according to an example embodiment;

FIG. 17 is a flowchart of a method of determining whether Hall sensors are arranged normally within a motor based on speeds calculated based on sensing signals, according to an example embodiment;

FIG. 18 illustrates a method of calculating a first speed based on a first sensing signal and calculating a second speed based on a second sensing signal, according to an example embodiment;

FIG. 19 is a flowchart of a method of determining a state of a motor based on a command current trajectory and an output current trajectory, according to an example embodiment;

FIG. 20 illustrates a command current trajectory and an output current trajectory, according to an example embodiment;

FIG. 21 is a flowchart of a method of determining a state of a motor based on a rotations per minute (RPM) change trajectory of a shaft of the motor, according to an example embodiment;

FIG. 22 illustrates an RPM change trajectory of a shaft of a motor, according to an example embodiment;

FIG. 23 is a flowchart of a method of transmitting information about a motor to a preset server, according to an example embodiment; and

FIG. 24 illustrates a magnet and a plurality of Hall sensors arranged within a motor, according to an example embodiment.

### DETAILED DESCRIPTION

Hereinafter, various example embodiments will be described with reference to the accompanying drawings. However, this is not intended to limit the present disclosure to specific embodiments, and it should be understood that various modifications, equivalents, and/or alternatives of the embodiments of the present disclosure are included.

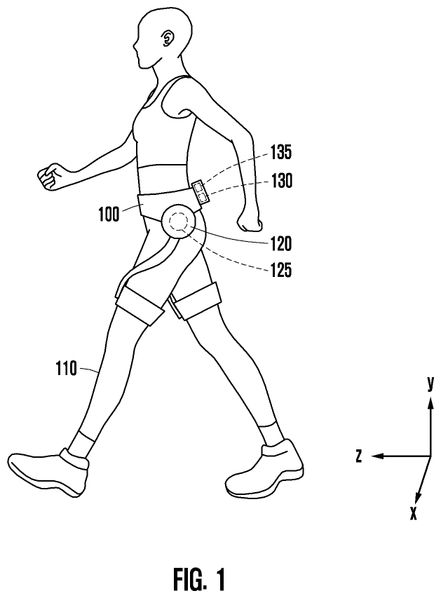

FIG. 1 is a diagram illustrating an overview of a wearable device worn on a body of a user, according to an example embodiment.

Referring to FIG. 1, in an embodiment, a wearable device 100 may be a device worn on a body of a user 110 to assist the user 110 in walking, exercising, and/or working. In an embodiment, the wearable device 100 may be used to measure a physical ability (e.g., a walking ability, an exercise ability, or an exercise posture) of the user 110. In embodiments, the term “wearable device” may be replaced with “wearable robot,” “walking assistance device,” or “exercise assistance device.” The user 110 may be a human or an animal, but is not limited thereto. The wearable device 100 may be worn on a body (e.g., a lower body (the legs, ankles, knees, etc.), an upper body (the torso, arms, wrists, etc.), or the waist) of the user 110 to apply an external force such as an assistance force and/or a resistance force to a body motion of the user 110. The assistance force may be a force applied in the same direction as the body motion direction of the user 110, the force to assist a body motion of the user 110. The resistance force may be a force applied in a direction opposite to the body motion direction of the user 110, the force hindering a body motion of the user 110. The term “resistance force” may also be referred to as “exercise load.”

In an embodiment, the wearable device 100 may operate in a walking assistance mode for assisting the user 110 in walking. In the walking assistance mode, the wearable device 100 may assist the user 110 in walking by applying an assistance force generated by a driving module 120 of the wearable device 100 to the body of the user 110. The wearable device 100 may enable the user 110 to walk independently or to walk for a long time by providing a force required for the user 110 to walk, thereby extending the walking ability of the user 110. The wearable device 100 may help in improving an abnormal walking habit or gait posture of a walker.

In an embodiment, the wearable device 100 may operate in an exercise assistance mode for enhancing the exercise effect of the user 110. In the exercise assistance mode, the wearable device 100 may impede a body movement of the user 110 or provide resistance to the body movement of the user 110 by applying a resistance force generated from the driving module 120 to the body of the user 110. When the wearable device 100 is a hip-type wearable device that is worn on a waist (or pelvis) and legs (e.g., thighs) of the user 110, the wearable device 100 may provide an exercise load to a leg motion of the user 110 while being worn on the legs, thereby enhancing the exercise effect on the legs of the user 110. In an embodiment, the wearable device 100 may apply an assistance force to the body of the user 110 to assist the user 110 in exercising. For example, when a person with a disability or an elderly person wants to exercise by wearing the wearable device 100, the wearable device 100 may provide an assistance force to assist a body motion during an exercise process. In an embodiment, the wearable device 100 may provide an assistance force and a resistance force in combination for each exercise section or time section, in such a manner of providing an assistance force in some exercise sections and a resistance force in other exercise sections.

In an embodiment, the wearable device 100 may operate in a physical ability measurement mode for measuring a physical ability of the user 110. The wearable device 100 may measure motion information of the user 110 using sensors (e.g., an angle sensor 125 and an inertial measurement unit (IMU) 135) provided in the wearable device 100 while the user 110 is walking or exercising, and evaluate the physical ability of the user 110 based on the measured motion information. For example, a gait index or an exercise ability indicator (e.g., a muscular strength, endurance, balance, or exercise posture) of the user 110 may be estimated based on the motion information of the user 110 measured by the wearable device 100. The physical ability measurement mode may include an exercise posture measurement mode to measure an exercise motion of the user 110.

In certain example embodiments, for convenience of description, the wearable device 100 is described as an example of a hip-type wearable device, as illustrated in FIG. 1, but the embodiments are not limited thereto. As described above, the wearable device 100 may be worn on body parts (e.g., upper arms, lower arms, hands, calves, and feet) other than the waist and legs (particularly, the thighs), and a shape and configuration of the wearable device 100 may vary depending on the body part on which the wearable device 100 is worn.

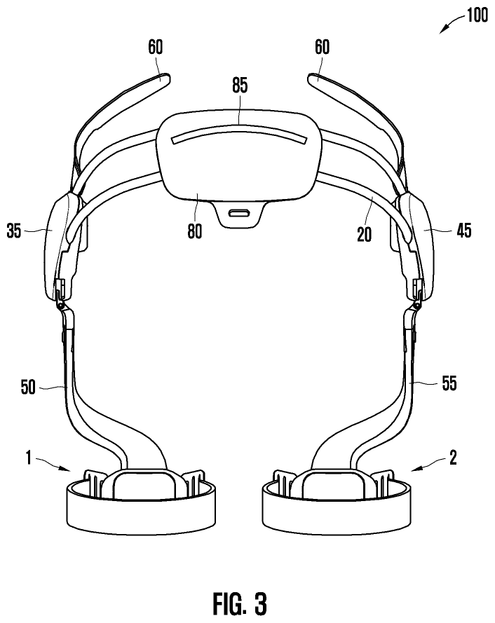

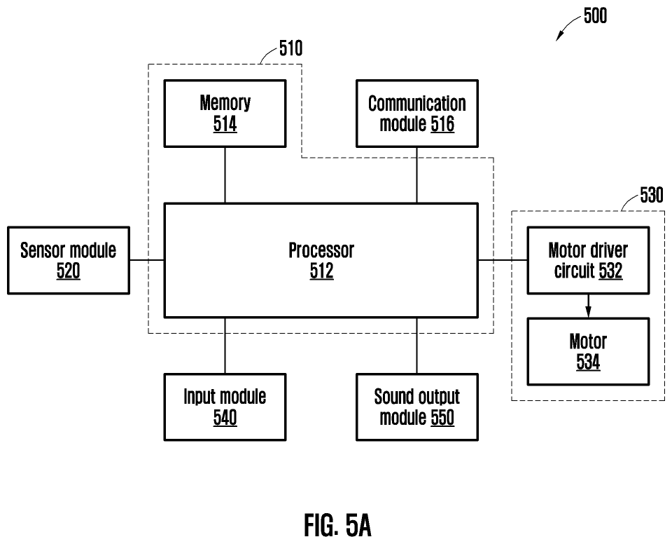

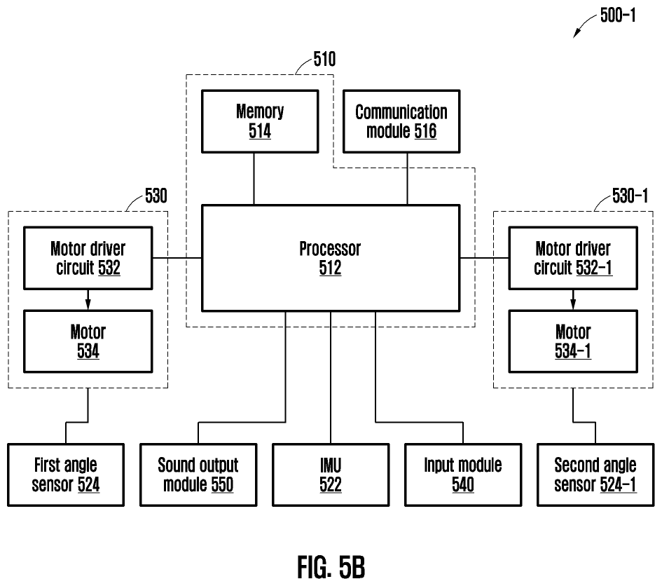

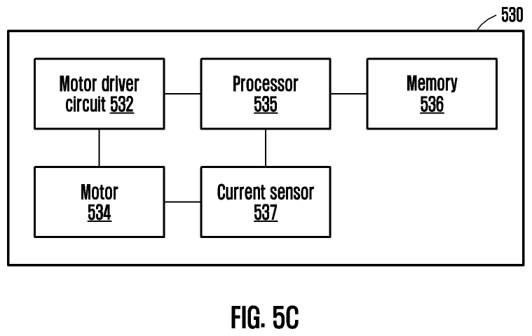

According to an embodiment, the wearable device 100 may include a support frame (e.g., leg support frames 50 and 55 and a waist support frame 20 of FIG. 3) configured to support the body of the user 110 when the wearable device 100 is worn on the body of the user 110, a sensor module (e.g., a sensor module 520 of FIG. 5A) configured to obtain sensor data including motion information on a body motion (e.g., a motion of a leg, and a motion of an upper body) of the user 110, the driving module 120 (e.g., driving modules 35 and 45 of FIG. 3) configured to generate torque to be applied to the legs of the user 110, and a control module 130 comprising processing circuitry (e.g., a control module 510 of FIGS. 5A and 5B) configured to control the wearable device 100.

The sensor module may include the angle sensor 125 and the IMU 135. The angle sensor 125 may measure a rotation angle of a leg support frame of the wearable device 100 corresponding to a hip joint angle value of the user 110. The rotation angle of the leg support frame measured by the angle sensor 125 may be estimated as a hip joint angle value (or a leg angle value) of the user 110. The angle sensor 125 may include, for example, an encoder and/or a Hall sensor. In an embodiment, the angle sensor 125 may be present near each of a right hip joint and a left hip joint of the user 110. The IMU 135 may include an acceleration sensor and/or an angular velocity sensor, and may measure a change in acceleration and/or angular velocity according to a motion of the user 110. The IMU 135 may measure, for example, an upper body motion value of the user 110 corresponding to a motion value of a waist support frame (or a base body (a base body 80 of FIG. 3)) of the wearable device 100. A motion value of the waist support frame measured by the IMU 135 may be estimated as an upper body motion value of the user 110.

In an embodiment, the control module 130 and the IMU 135 may be arranged within the base body (e.g., the base body 80 of FIG. 3) of the wearable device 100. The base body may be disposed on, directly or indirectly, a lumbar region (an area of the lower back) of the user 110 while the user 110 is wearing the wearable device 100. The base body may be formed or attached to an outer side of the waist support frame of the wearable device 100. The base body may be mounted on the lumbar region of the user 110 to provide a cushioning feeling to the lower back of the user 110 and may support the lower back of the user 110 together with the waist support frame.

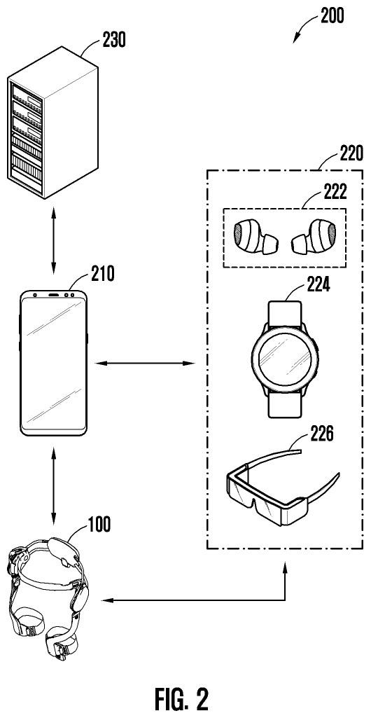

FIG. 2 is a diagram illustrating an exercise management system including a wearable device and an electronic device, according to an embodiment.

Referring to FIG. 2, an exercise management system 200 may include a wearable device 100 to be worn on a body of a user, an electronic device 210, another wearable device 220, and a server 230. In an embodiment, at least one (e.g., the other wearable device 220 or the server 230) of the above devices may be omitted from the exercise management system 200, or one or more other devices (e.g., an exclusive controller device of the wearable device 100) may be added thereto.

In an embodiment, the wearable device 100 may be worn on the body of the user in a walking assistance mode to assist a motion of the user. For example, the wearable device 100 may be worn on legs of the user to help the user in walking by generating an assistance force for assisting a leg motion of the user.

In an embodiment, the wearable device 100 may generate a resistance force for hindering a body motion of the user or an assistance force for assisting a body motion of the user and apply the generated resistance force or assistance force to the body of the user to enhance the exercise effect of the user in an exercise assistance mode. In the exercise assistance mode, the user may select, through the electronic device 210, an exercise program (e.g., squat, split lunge, dumbbell squat, lunge and knee up, stretching, or the like) to perform using the wearable device 100 and/or an exercise intensity to be applied to the wearable device 100. The wearable device 100 may control a driving module of the wearable device 100 according to the exercise program selected by the user and obtain sensor data including motion information of the user through a sensor module. The wearable device 100 may adjust the strength of the resistance force or assistance force applied to the user according to the exercise intensity selected by the user. For example, the wearable device 100 may control the driving module to generate a resistance force corresponding to the exercise intensity selected by the user.

In an embodiment, the wearable device 100 may be used to measure a physical ability of the user by interworking with the electronic device 210. The wearable device 100 may operate in a physical ability measurement mode, which is a mode for measuring the physical ability of the user, under a control of the electronic device 210, and may transmit sensor data obtained by a motion of the user in the physical ability measurement mode to the electronic device 210. The electronic device 210 may estimate the physical ability of the user by analyzing the sensor data received from the wearable device 100.

The electronic device 210 may communicate with the wearable device 100 and may remotely control the wearable device 100 or provide the user with state information about a state (e.g., a booting state, a charging state, a sensing state, or an error state) of the wearable device 100. The electronic device 210 may receive sensor data obtained by a sensor of the wearable device 100 from the wearable device 100 and estimate the physical ability of the user or an exercise result based on the received sensor data. In an embodiment, when the user exercises wearing the wearable device 100, the wearable device 100 may obtain sensor data including motion information of the user using sensors and transmit the obtained sensor data to the electronic device 210. The electronic device 210 may extract a motion value of the user from the sensor data and evaluate an exercise posture of the user based on the extracted motion value. The electronic device 210 may provide the user with an exercise posture measured value and exercise posture evaluation information related to the exercise posture of the user through a graphical user interface (GUI).

In an embodiment, the electronic device 210 may execute a program (e.g., an application) configured to control the wearable device 100, and the user may adjust an operation or a set value of the wearable device 100 (e.g., the magnitude of torque output from a driving module (e.g., driving modules 35 and 45 of FIG. 3), the volume of audio output from a sound output module (e.g., a sound output module 550 of FIGS. 5A and 5B), or the brightness of a lighting unit (e.g., a lighting unit 85 of FIG. 3)) through the corresponding program. The program executed by the electronic device 210 may provide a GUI for interaction with the user. The electronic device 210 may be a device in various forms. For example, the electronic device 210 may include, but is not limited to, a portable communication device (e.g., a smartphone), a computer device, an access point, a portable multimedia device, or a home appliance device (e.g., a television, an audio device, a projector device).

According to an embodiment, the electronic device 210 may be connected to the server 230 using short-range wireless communication or cellular communication. The server 230 may receive user profile information of the user who uses the wearable device 100 from the electronic device 210 and store and manage the received user profile information. The user profile information may include, for example, information about at least one of the name, age, gender, height, weight, or body mass index (BMI). The server 230 may receive exercise history information about an exercise performed by the user from the electronic device 210 and store and manage the received exercise history information. The server 230 may provide the electronic device 210 with various exercise programs or physical ability measurement programs that may be provided to the user.

According to an embodiment, the wearable device 100 and/or the electronic device 210 may be connected, directly or indirectly, to the other wearable device 220. The other wearable device 220 may include, for example, wireless earphones 222, a smartwatch 224, or smart glasses 226, but is not limited thereto. In an embodiment, the smartwatch 224 may measure a biosignal including heart rate information of the user and transmit the measured biosignal to the electronic device 210 and/or the wearable device 100. The electronic device 210 may estimate the heart rate information (e.g., a current heart rate, a maximum heart rate, and an average heart rate) of the user based on the biosignal received from the smartwatch 224 and provide the estimated heart rate information to the user.

In an embodiment, the exercise result information, physical ability information, and/or exercise posture evaluation information evaluated by the electronic device 210 may be transmitted to the other wearable device 220 and provided to the user through the other wearable device 220. State information of the wearable device 100 may also be transmitted to the other wearable device 220 and provided to the user through the other wearable device 220. In an embodiment, the wearable device 100, the electronic device 210, and the other wearable device 220 may be connected to each other through wireless communication (e.g., Bluetooth communication or wireless-fidelity (Wi-Fi) communication).

In an embodiment, the wearable device 100 may provide (or output) feedback (e.g., visual feedback, auditory feedback, or haptic feedback) corresponding to a state of the wearable device 100 according to a control signal received from the electronic device 210. For example, the wearable device 100 may provide visual feedback through the lighting unit (e.g., the lighting unit 85 of FIG. 3) and provide auditory feedback through the sound output module (e.g., the sound output module 550 of FIGS. 5A and 5B). The wearable device 100 may include a haptic module and provide haptic feedback in the form of vibration to the body of the user through the haptic module. The electronic device 210 may also provide (or output) feedback (e.g., visual feedback, auditory feedback, or haptic feedback) corresponding to the state of the wearable device 100.

In an embodiment, the electronic device 210 may present a personalized exercise goal to the user in the exercise assistance mode. The personalized exercise goal may include respective target amounts of exercise for exercise types (e.g., strength exercise, balance exercise, and aerobic exercise) desired by the user, determined by the electronic device 210 and/or the server 230. When the server 230 determines a target amount of exercise, the server 230 may transmit information about the determined target amount of exercise to the electronic device 210. The electronic device 210 may personalize and present the target amounts of exercise for the exercise types, such as strength exercise, aerobic exercise, and balance exercise, according to a desired exercise program (e.g., squat, split lunge, or a lunge and knee up) and/or physical characteristics (e.g., the age, height, weight, and BMI) of the user. The electronic device 210 may display a GUI screen displaying the target amounts of exercise for the respective exercise types on a display.

In an embodiment, the electronic device 210 and/or the server 230 may include a database in which information about a plurality of exercise programs to be provided to the user through the wearable device 100 is stored. To achieve an exercise goal of the user, the electronic device 210 and/or the server 230 may recommend an exercise program suitable for the user. The exercise goal may include, for example, at least one of muscle strength improvement, physical strength improvement, cardiovascular endurance improvement, core stability improvement, flexibility improvement, or symmetry improvement. The electronic device 210 and/or the server 230 may store and manage the exercise program performed by the user, results of performing the exercise program, and the like.

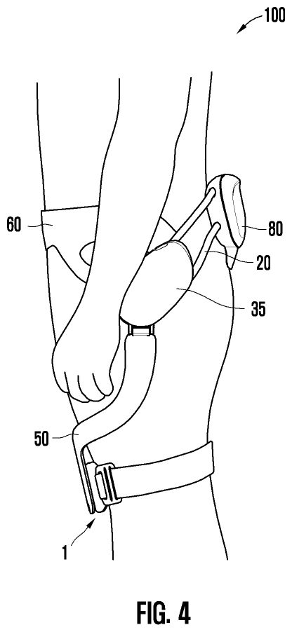

FIG. 3 is a rear schematic view of a wearable device, according to an embodiment. FIG. 4 is a left side view of a wearable device, according to an embodiment.

Referring to FIGS. 3 and 4, the wearable device 100 according to an embodiment may include the base body 80, the waist support frame 20, the driving modules 35 and 45, the leg support frames 50 and 55, thigh fastening portions 1 and 2, and a waist fastening portion 60. The base body 80 may include the lighting unit 85. In an embodiment, at least one (e.g., the lighting unit 85) of the above components may be omitted from the wearable device 100, or one or more other components (e.g., a haptic module) may be added to the wearable device 100.

The base body 80 may be disposed on, directly or indirectly, a lumbar region of a user while the user is wearing the wearable device 100. The base body 80 may be mounted on the lumbar region of the user to provide a cushioning feeling to the lower back of the user and may support the lower back of the user. The base body 80 may be hung on a hip region (an area of the hips) of the user to prevent or reduce chances of the wearable device 100 from being separated downward due to gravity while the user is wearing the wearable device 100. The base body 80 may distribute a portion of a weight of the wearable device 100 to the lower back of the user while the user is wearing the wearable device 100. The base body 80 may be connected, directly or indirectly, to the waist support frame 20. Waist support frame connecting elements (not shown) to be connected, directly or indirectly, to the waist support frame 20 may be provided at both end portions of the base body 80.

In an embodiment, the lighting unit 85 may be arranged on an outer side of the base body 80. The lighting unit 85 may include a light source (e.g., a light-emitting diode (LED)). The lighting unit 85 may emit light under a control of a control module (not shown) (e.g., the control module 510 of FIGS. 5A and 5B). According to an embodiment, the control module may control the lighting unit 85 to provide (or output) visual feedback corresponding to the state of the wearable device 100 to the user through the lighting unit 85.

The waist support frame 20 may extend from both end portions of the base body 80. The lumbar region of the user may be accommodated inside the waist support frame 20. The waist support frame 20 may include at least one rigid body beam. Each beam may be in a curved shape having a preset curvature to enclose the lumbar region of the user. The waist fastening portion 60 may be connected, directly or indirectly, to an end portion of the waist support frame 20. The driving modules 35 and 45 may be connected, directly or indirectly, to the waist support frame 20.

In an embodiment, the control module, an IMU (not shown) (e.g., the IMU 135 of FIG. 1 or an IMU 522 of FIG. 5B), a communication module (not shown) (e.g., a communication module 516 of FIGS. 5A and 5B, comprising communication circuitry), and a battery (not shown) may be arranged inside the base body 80. The base body 80 may protect the control module, the IMU, the communication module, and the battery. The control module, comprising processing circuitry, may generate a control signal for controlling an operation of the wearable device 100. The control module may include a control circuit including a processor configured to control actuators of the driving modules 35 and 45 and memory. The control module may further include a power supply module (not shown) to supply power from a battery to each of the components of the wearable device 100.

In an embodiment, the wearable device 100 may include a sensor module (not shown) (e.g., the sensor module 520 of FIG. 5A) configured to obtain sensor data from at least one sensor. The sensor module may obtain sensor data that changes according to a motion of the user. In an embodiment, the sensor module may obtain sensor data including motion information of the user and/or motion information of the components of the wearable device 100. The sensor module may include, for example, an IMU (e.g., the IMU 135 of FIG. 1 or the IMU 522 of FIG. 5B) configured to measure an upper body motion value of the user or a motion value of the waist support frame 20, and an angle sensor (e.g., the angle sensor 125 of FIG. 1 or a first angle sensor 524 and a second angle sensor 524-1 of FIG. 5B) configured to measure a hip joint angle value of the user or a motion value of the leg support frames 50 and 55, but is not limited thereto. For example, the sensor module may further include at least one of a position sensor, a temperature sensor, a biosignal sensor, or a proximity sensor.

The waist fastening portion 60 may be connected, directly or indirectly, to the waist support frame 20 to fasten the waist support frame 20 to a waist of the user. The waist fastening portion 60 may include, for example, a pair of belts.

The driving modules 35 and 45 may generate an external force (or torque) to be applied to the body of the user based on the control signal generated by the control module. For example, the driving modules 35 and 45 may generate an assistance force or resistance force to be applied to legs of the user. In an embodiment, the driving modules 35 and 45 may include a first driving module 45 disposed in a position corresponding to a position of a right hip joint of the user, and a second driving module 35 disposed in a position corresponding to a position of a left hip joint of the user. The first driving module 45 may include a first actuator and a first joint member, and the second driving module 35 may include a second actuator and a second joint member. The first actuator may provide power to be transmitted to the first joint member, and the second actuator may provide power to be transmitted to the second joint member. The first actuator and the second actuator may each include a motor configured to generate power (or a torque) by receiving electric power from the battery. When the motor is supplied with electric power and driven, the motor may generate a force (an assistance force) for assisting a body motion of the user or a force (a resistance force) for hindering a body motion of the user. In an embodiment, the control module may adjust the strength and direction of the force generated by the motor by adjusting the voltage and/or current supplied to the motor.

In an embodiment, the first joint member and the second joint member may receive power from the first actuator and the second actuator, respectively, and may apply an external force to the body of the user based on the received power. The first joint member and the second joint member may be arranged at positions corresponding to joint portions of the user, respectively. One side of the first joint member may be connected, directly or indirectly, to the first actuator, and the other side of the first joint member may be connected, directly or indirectly, to a first leg support frame 55. The first joint member may be rotated by the power received from the first actuator. An encoder or a Hall sensor that may operate as an angle sensor configured to measure the rotational angle of the first joint member (corresponding to the joint angle of the user) may be arranged on one side of the first joint member. One side of the second joint member may be connected, directly or indirectly, to the second actuator, and the other side of the second joint member may be connected, directly or indirectly, to a second leg support frame 50. The second joint member may be rotated by the power received from the second actuator. An encoder or a Hall sensor that may operate as an angle sensor configured to measure a rotation angle of the second joint member may be arranged on one side of the second joint member.

In an embodiment, the first actuator may be arranged in a lateral direction of the first joint member, and the second actuator may be arranged in a lateral direction of the second joint member. A rotation axis of the first actuator and a rotation axis of the first joint member may be spaced apart from each other, and a rotation axis of the second actuator and a rotation axis of the second joint member may also be spaced apart from each other. However, embodiments are not limited thereto, and an actuator and a joint member may share a rotation axis. In an embodiment, each actuator may be spaced apart from a corresponding joint member. In this case, the driving module 35, 45 may further include a power transmission module (not shown) configured to transmit power from the actuator to the joint member. The power transmission module may be a rotary body, such as a gear, or a longitudinal member, such as a wire, a cable, a string, a spring, a belt, or a chain. However, the scope of the embodiment is not limited by a positional relationship between an actuator and a joint member and a power transmission structure described above.

In an embodiment, the leg support frame 50, 55 may support a leg (e.g., a thigh) of the user when the wearable device 100 is worn on the leg of the user. For example, the leg support frame 50, 55 may transmit power (a torque) generated by the driving module 35, 45 to the thigh of the user, and the power may function as an external force to be applied to a motion of the leg of the user. As one end portion of the leg support frame 50, 55 is connected, directly or indirectly, to a joint member to rotate and the other end portion of the leg support frame 50, 55 is connected, directly or indirectly, to the thigh fastening portion 1, 2, the leg support frame 50, 55 may transmit the power generated by the driving module 35, 45 to the thigh of the user while supporting the thigh of the user. For example, the leg support frame 50, 55 may push or pull the thigh of the user. The leg support frame 50, 55 may extend in a longitudinal direction of the thigh of the user. The leg support frame 50, 55 may be folded to wrap around at least a portion of a thigh circumference of the user. The leg support frames 50 and 55 may include a first leg support frame 55 configured to support a right leg of the user, and a second leg support frame 50 configured to support a left leg of the user.

The thigh fastening portions 1 and 2 may be connected, directly or indirectly, to the leg support frames 50 and 55 and may fasten the leg support frames 50 and 55 to the thighs. The thigh fastening portions 1 and 2 may include a first thigh fastening portion 2 configured to fasten the first leg support frame 55 to a right thigh of the user, and a second thigh fastening portion 1 configured to fasten the second leg support frame 50 to a left thigh of the user.

In an embodiment, the first thigh fastening portion 2 may include a first cover, a first fastening frame, and a first strap, and the second thigh fastening portion 1 may include a second cover, a second fastening frame, and a second strap. The first cover and the second cover may apply torques generated by the driving modules 35 and 45 to the thighs of the user. The first cover and the second cover may be arranged on one sides of the thighs of the user to push or pull the thighs of the user. For example, the first cover and the second cover may be arranged on front surfaces of the thighs of the user. The first cover and the second cover may be arranged in circumferential directions of the thighs of the user. The first cover and the second cover may extend to both sides from the other end portions of the leg support frames 50 and 55 and may include curved surfaces corresponding to the thighs of the user. One end of each of the first cover and the second cover may be connected, directly or indirectly, to a fastening frame, and the other end thereof may be connected, directly or indirectly, to a strap.

The first fastening frame and the second fastening frame may be arranged, for example, to surround at least some portions of the circumferences of the thighs of the user, thereby preventing or reducing chances of the thighs of the user from being separated from the leg support frames 50 and 55. The first fastening frame may have a fastening structure that connects the first cover and the first strap, and the second fastening frame may have a fastening structure that connects the second cover and the second strap.

The first strap may enclose the remaining portion of the circumference of the right thigh of the user that is not covered by the first cover and the first fastening frame, and the second strap may enclose the remaining portion of the circumference of the left thigh of the user that is not covered by the second cover and the second fastening frame. The first strap and the second strap may include, for example, an elastic material (e.g., a band).

FIGS. 5A and 5B are diagrams illustrating a configuration of a control system of a wearable device, according to an embodiment.

Referring to FIG. 5A, the wearable device 100 may be controlled by a control system 500. The control system 500 may include the control module 510, the communication module 516, the sensor module 520, a driving module 530, an input module 540, and the sound output module 550. In an embodiment, at least one (e.g., the sound output module 550) of the above components may be omitted from the control system 500, or one or more other components (e.g., a haptic module) may be added to the control system 500.

The driving module 530 may include a motor 534 configured to generate power (e.g., torque), and a motor driver circuit 532 to drive the motor 534. Although FIG. 5A illustrates the driving module 530 including one motor driver circuit 532 and one motor 534, the example of FIG. 5A is merely an example. Referring to FIG. 5B, a control system 500-1 may include a plurality of (e.g., two or more) motor driver circuits 532 and 532-1 and a plurality of (e.g., two or more) motors 534 and 534-1. The driving module 530 including the motor driver circuit 532 and the motor 534 may correspond to the first driving module 45 of FIG. 3, and a driving module 530-1 including the motor driver circuit 532-1 and the motor 534-1 may correspond to the second driving module 35 of FIG. 3. The following descriptions of the motor driver circuit 532 and the motor 534 may also be respectively applicable to the motor driver circuit 532-1 and the motor 534-1 illustrated in FIG. 5B.

Referring back to FIG. 5A, the sensor module 520 may include a sensor circuit including at least one sensor. The sensor module 520 may obtain sensor data including motion information of a user or motion information of the wearable device 100. The sensor module 520 may transmit the obtained sensor data to the control module 510. The sensor module 520 may include an IMU 522 and an angle sensor (e.g., the first angle sensor 524 and the second angle sensor 524-1) as illustrated in FIG. 5B. The IMU 522 may measure an upper body motion value of the user. For example, the IMU 522 may sense X-axis, Y-axis, and Z-axis accelerations and X-axis, Y-axis, and Z-axis angular velocities according to a motion of the user. The IMU 522 may be used to measure, for example, at least one of a forward and backward tilt, a left and right tilt, or a rotation of the body of the user. In addition, the IMU 522, comprising a sensor and/or circuitry, may obtain motion values (e.g., acceleration values and angular velocity values) of a waist support frame (e.g., the waist support frame 20 of FIG. 3) of the wearable device 100. The motion values of the waist support frame may correspond to upper body motion values of the user.

The angle sensor may measure a hip joint angle value according to a leg motion of the user. Sensor data that may be measured by the angle sensor may include, for example, a hip joint angle value of a right leg, a hip joint angle value of a left leg, and information on a direction of a motion of a leg. For example, the first angle sensor 524 of FIG. 5B may obtain the hip joint angle value of the right leg of the user, and the second angle sensor 524-1 may obtain the hip joint angle value of the left leg of the user. The first angle sensor 524 and the second angle sensor 524-1 may each include, for example, an encoder and/or a Hall sensor. In addition, the first angle sensor 524 and the second angle sensor 524-1 may obtain motion values of the leg support frames 50 and 55 of the wearable device 100. For example, the first angle sensor 524 may obtain a motion value of the first leg support frame 55, and the second angle sensor 524-1 may obtain a motion value of the second leg support frame 50. The motion values of the leg support frames 50 and 55 may correspond to the hip joint angle values.

In an embodiment, the sensor module 520 may further include at least one of a position sensor configured to obtain a position value of the wearable device 100, a proximity sensor configured to sense the proximity of an object, a biosignal sensor configured to detect a biosignal of the user, or a temperature sensor configured to measure an ambient temperature.

The input module 540 may receive a command or data to be used by another component (e.g., the processor 512) of the wearable device 100 from the outside (e.g., a user) of the wearable device 100. The input module 540 may include an input component circuit. The input module 540 may include, for example, a key (e.g., a button) or a touch screen.

The sound output module 550 may output a sound signal to the outside of the wearable device 100. The sound output module 550 may provide auditory feedback to the user. For example, the sound output module 550 may include a speaker configured to play back a guiding sound signal (e.g., an operation start sound, an operation error alarm, or an exercise start alarm), music content, or a guiding voice for auditorily informing predetermined information (e.g., exercise result information or exercise posture evaluation information).

In an embodiment, the control system 500 may further include a battery (not shown) configured to supply power to each component of the wearable device 100. The wearable device 100 may convert the power of the battery into power suitable for an operating voltage of each component of the wearable device 100 and supply the converted power to each component.

The driving module 530 may generate an external force to be applied to a leg of the user under the control of the control module 510. The driving module 530 may generate a torque to be applied to the legs of the user based on a control signal generated by the control module 510. The control module 510 may transmit the control signal to the motor driver circuit 532. The motor driver circuit 532 may control the operation of the motor 534 by generating a current signal (or voltage signal) corresponding to the control signal and supplying the generated current signal to the motor 534. In some cases, the current signal may not be supplied to the motor 534. When the motor 534 is supplied with the current signal and driven, the motor 534 may generate a torque for an assistance force for assisting a leg motion of the user or a resistance force for hindering a leg motion of the user.

The control module 510 may control an overall operation of the wearable device 100 and may generate a control signal to control each component (e.g., the communication module 516 or the driving module 530). The control module 510 may include the processor 512 and memory 514.

The processor 512 may execute, for example, software to control at least one other component (e.g., a hardware or software component) of the wearable device 100 connected, directly or indirectly, to the processor 512, and may perform a variety of data processing or computation. The software may include an application for providing a GUI. According to an embodiment, as at least a part of data processing or computation, the processor 512 may store instructions or data received from another component (e.g., the communication module 516) in the memory 514, may process the instructions or the data stored in the memory 514, and may store result data in the memory 514. According to an embodiment, the processor 512 may include a main processor (e.g., a central processing unit (CPU) or an application processor (AP)), or an auxiliary processor (e.g., a graphics processing unit (GPU), a neural processing unit (NPU), an image signal processor (ISP), a sensor hub processor, or a communication processor (CP)) that is operable independently of or in conjunction with the main processor. The auxiliary processor may be implemented separately from the main processor or as a part of the main processor.

Each “processor” herein includes processing circuitry, and/or may include multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The memory 514 may store a variety of data used by at least one component (e.g., the processor 512) of the control module 510. The variety of data may include, for example, software, sensor data, input data or output data for instructions related thereto. The memory 514 may include a volatile memory or a non-volatile memory (e.g., random-access memory (RAM), dynamic RAM (DRAM), or static RAM (SRAM)).

The communication module 516 may support establishing a direct (e.g., wired) communication channel or a wireless communication channel between the control module 510 and another component of the wearable device 100 or an external electronic device (e.g., the electronic device 210 or the other wearable device 220 of FIG. 2) and performing communication via the established communication channel. The communication module 516 may include a communication circuit configured to perform a communication function. For example, the communication module 516 may receive a control signal from an electronic device (e.g., the electronic device 210) and transmit the sensor data obtained by the sensor module 520 to the electronic device. According to an embodiment, the communication module 516 may include one or more CPs (not shown) that are operable independently of the processor 512 and that support direct (e.g., wired) communication or wireless communication. According to an embodiment, the communication module 516 may include a wireless communication module (e.g., a cellular communication module, a short-range wireless communication module, or a global navigation satellite system (GNSS) communication module), and/or a wired communication module. A corresponding one of the above communication modules may communicate with another component of the wearable device 100 and/or an external electronic device via a short-range communication network, such as Bluetooth™, Wi-Fi, or infrared data association (IrDA), or a long-range communication network, such as a legacy cellular network, a 5G network, a next-generation communication network, the Internet, or a computer network (e.g., a local area network (LAN) or a wide region network (WAN)).

In an embodiment, the control system 500, 500-1 may further include a haptic module (not shown). The haptic module may provide haptic feedback to the user under the control of the processor 512. The haptic module may convert an electrical signal into a mechanical stimulus (e.g., a vibration or a movement) or an electrical stimulus which may be recognized by a user via his or her tactile sensation or kinesthetic sensation. The haptic module may include a motor, a piezoelectric element, or an electrical stimulation device. In an embodiment, the haptic module may be positioned in at least one of the base body (e.g., the base body 80), the first thigh fastening portion 2, or the second thigh fastening portion 1.

FIG. 5C is a diagram illustrating a configuration of a driving module according to an embodiment.

According to an embodiment, the driving module 530 may include the motor driver circuit 532, the motor 534, a processor 535, the memory 536, and a current sensor 537. Each driving module herein may thus, for example, include one or more of circuitry, a motor, a processor(s), a sensor, and/or a memory. Some driving modules my simply include, for example, a motor and circuitry, with other elements such as a processor(s), memory (ies), and/or “sensor” being optional.

According to an embodiment, the driving module 530 may include the processor 535 and the memory 536 that stores instructions executable by the processor 535. When the instructions are executed by the processor 535, the instructions may cause the driving module 530 to determine a state of the motor 534. For example, the processor 535 and the memory 536 may configure a micro controller unit (MCU).

The driving module 530 may further include the motor 534 and the current sensor 537. For example, the current sensor 537 may sense a value of current flowing through each of coils (e.g., three-phase coils) of the motor 534.

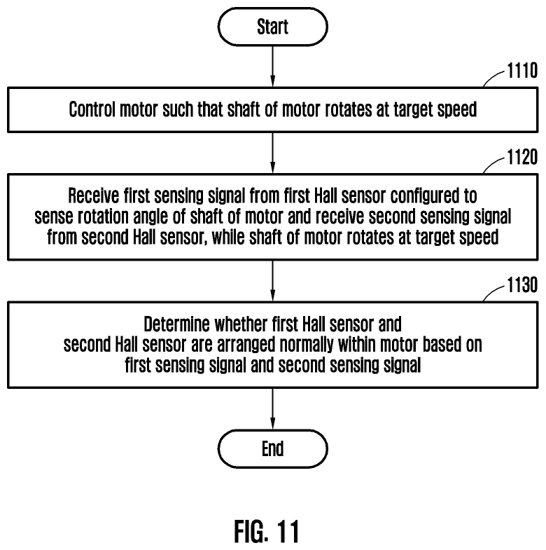

Hereinafter, a method by which a driving module determines a state of a motor is described in detail with reference to FIGS. 11 to 23.

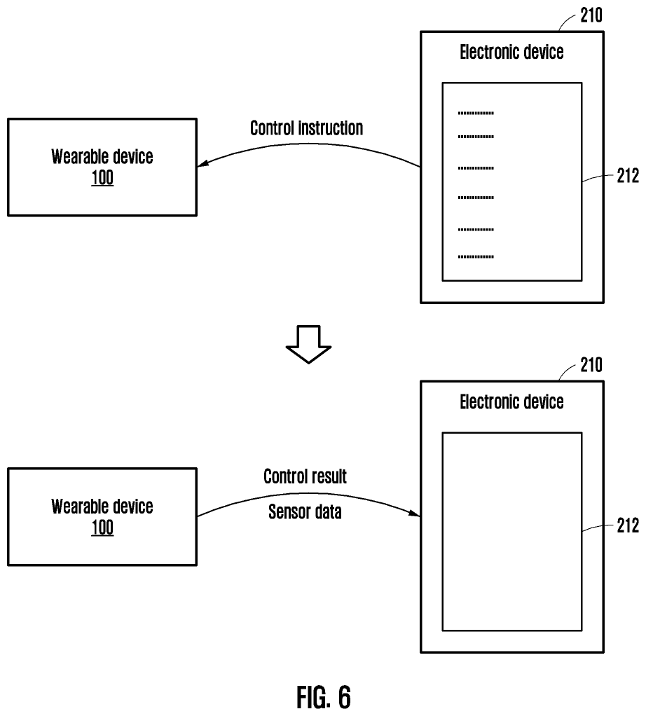

FIG. 6 is a diagram illustrating an interaction between a wearable device and an electronic device, according to an embodiment.

Referring to FIG. 6, the wearable device 100 may communicate with the electronic device 210. For example, the electronic device 210 may be a user terminal of a user who uses the wearable device 100 or a controller device dedicated to the wearable device 100. In an embodiment, the wearable device 100 and the electronic device 210 may be connected to each other through short-range wireless communication (e.g., Bluetooth communication or Wi-Fi communication).

In an embodiment, the electronic device 210 may check a state of the wearable device 100 or execute an application to control or operate the wearable device 100. A screen of a user interface (UI) may be displayed to control an operation of the wearable device 100 or determine an operation mode of the wearable device 100 on a display 212 of the electronic device 210 through the execution of the application. The UI may be, for example, a GUI.

In an embodiment, the user may input an instruction for controlling the operation of the wearable device 100 (e.g., an execution instruction to a walking assistance mode, an exercise assistance mode, or a physical ability measurement mode) or change settings of the wearable device 100 through a GUI screen on the display 212 of the electronic device 210. The electronic device 210 may generate a control instruction (or control signal) corresponding to an operation control instruction or a setting change instruction input by the user and transmit the generated control instruction to the wearable device 100. The wearable device 100 may operate according to the received control instruction and transmit a control result according to the control instruction and/or sensor data measured by the sensor module of the wearable device 100 to the electronic device 210. The electronic device 210 may provide the user with result information (e.g., walking ability information, exercise ability information, or exercise posture evaluation information) derived by analyzing the control result and/or the sensor data through the GUI screen.

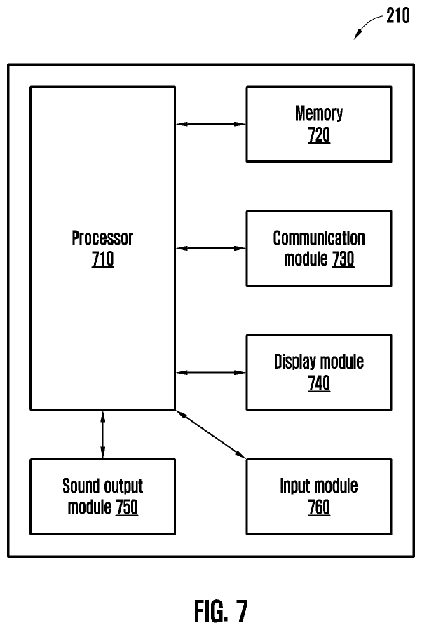

FIG. 7 is a diagram illustrating a configuration of an electronic device, according to an embodiment.

Referring to FIG. 7, the electronic device 210 may include a processor 710, memory 720, a communication module 730, a display module 740, a sound output module 750, and an input module 760. In an embodiment, at least one (e.g., the sound output module 750) of the above components may be omitted from the electronic device 210, or one or more other components (e.g., a sensor module and a battery) may be added to the electronic device 210.

The processor 710 may control at least one other component (e.g., a hardware or software component) of the electronic device 210, and may perform a variety of data processing or computation. According to an embodiment, as at least a part of data processing or computation, the processor 710 may store instructions or data received from another component (e.g., the communication module 730) in the memory 720, process the instructions or data stored in the memory 720, and store result data in the memory 720.

In an embodiment, the processor 710 may include a main processor (e.g., a CPU or an AP) or an auxiliary processor (e.g., a GPU, an NPU, an ISP, a sensor hub processor, or a CP) that is operable independently of or in conjunction with the main processor.

The memory 720 may store a variety of data used by at least one component (e.g., the processor 710 or the communication module 730) of the electronic device 210. The data may include, for example, a program (e.g., an application), and input data or output data for a command related thereto. The memory 720 may include at least one instruction executable by the processor 710. The memory 720 may include, for example, a volatile memory or a non-volatile memory.

The communication module 730 may support establishing a direct (e.g., wired) communication channel or a wireless communication channel between the electronic device 210 and another electronic device (e.g., the wearable device 100, the other wearable device 220, or the server 230) and performing communication via the established communication channel. The communication module 730 may include a communication circuit configured to perform a communication function. The communication module 730 may include one or more CPs that are operable independently of the processor 710 (e.g., an AP) and that support direct (e.g., wired) communication or wireless communication. According to an embodiment, the communication module 290 may include a wireless communication module configured to perform wireless communication (e.g., a Bluetooth communication module, a cellular communication module, a Wi-Fi communication module, or a GNSS communication module) or a wired communication module (e.g., a LAN communication module or a power line communication (PLC) module). For example, the communication module 730 may transmit a control instruction to the wearable device 100 and receive, from the wearable device 100, at least one of sensor data including body motion information of the user who is wearing the wearable device 100, state data of the wearable device 100, or control result data corresponding to the control instruction.

The display module 740 may visually provide information to the outside (e.g., a user) of the electronic device 210. The display module 740 may include, for example, a liquid-crystal display (LCD) or organic light-emitting diode (OLED) display, a hologram device, or a projector device. The display module 740 may further include a control circuit configured to control the driving of a display. In an embodiment, the display module 740 may include a touch sensor adapted to sense a touch, or a pressure sensor adapted to measure an intensity of a force incurred by the touch.

The sound output module 750 may output a sound signal to the outside of the electronic device 210. The sound output module 750 may include a guide sound signal (e.g., a driving start sound or an operation error notification sound) based on a state of the wearable device 100 and a speaker for playing musical content or a guide voice. When it is determined that the wearable device 100 is not properly worn on the body of the user, the sound output module 750 may output a guiding voice for informing the user is wearing the wearable device 100 abnormally or for guiding the user to wear the wearable device 100 normally. The sound output module 750 may output, for example, a guiding voice corresponding to exercise evaluation information or exercise result information obtained by evaluating an exercise of the user.

The input module 760 may receive a command or data to be used by another component (e.g., the processor 710) of the electronic device 210, from the outside (e.g., a user) of the electronic device 210. The input module 760 may include an input component circuit and may receive a user input. The input module 760 may include, for example, a key (e.g., a button) or a touch screen.

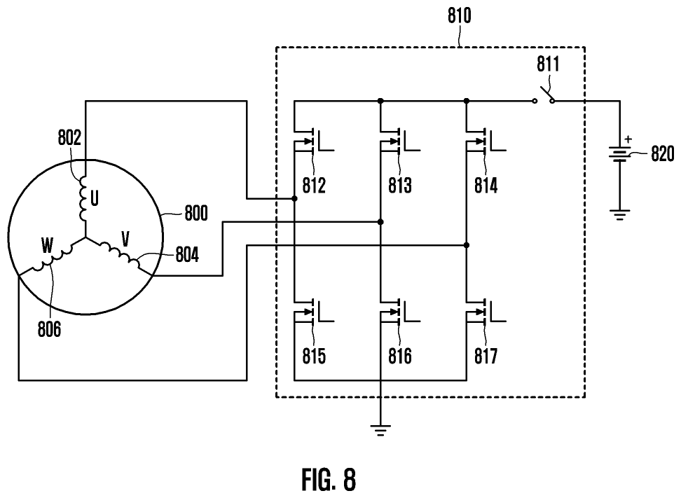

FIG. 8 illustrates a motor and motor driver circuit, according to an embodiment.

According to an embodiment, a motor 800 (e.g., the motor 534 of FIG. 5A) may include a U-phase coil 802, a V-phase coil 804, and a W-phase coil 806. The motor 800 may be a three-phase motor.

According to an embodiment, a motor driver circuit 810 (e.g., the motor driver circuit 532 of FIG. 5A) may include a switch 811, a first transistor 812, a second transistor 813, a third transistor 814, a fourth transistor 815, a fifth transistor 816, and a sixth transistor 817. Each of the first transistor 812, the second transistor 813, and the third transistor 814 may be a top transistor of the motor driver circuit 810. Each of the fourth transistor 815, the fifth transistor 816, and the sixth transistor 817 may be a bottom transistor of the motor driver circuit 810.

The switch 811 may be used to control a driving voltage applied to the motor driver circuit 810. The driving voltage may be generated by a driving power source 820. For example, the driving power source 820 may be a system power source or a battery.

A source terminal of the first transistor 812 may be connected, directly or indirectly, to the U-phase coil 802 of the motor 800. A drain terminal of the fourth transistor 815 may be connected, directly or indirectly, to the U-phase coil 802 of the motor 800. A source terminal of the second transistor 813 may be connected, directly or indirectly, to the V-phase coil 804 of the motor 800. A drain terminal of the fifth transistor 816 may be connected, directly or indirectly, to the V-phase coil 804 of the motor 800. A source terminal of the third transistor 814 may be connected, directly or indirectly, to the W-phase coil 806 of the motor 800. A drain terminal of the sixth transistor 817 may be connected, directly or indirectly, to the W-phase coil 806 of the motor 800.

According to an embodiment, a processor (e.g., the processor 512 of FIG. 5A) of a control module (e.g., the control module 130 of FIG. 1 or the control module 510 of FIG. 5A) of a wearable device (e.g., the wearable device 100 of FIG. 1) may control operations of the first transistor 812, the second transistor 813, the third transistor 814, the fourth transistor 815, the fifth transistor 816, and the sixth transistor 817 so that the motor 800 may be controlled based on pulse width modulation (PWM). For example, the processor may control a gate voltage of each of the first transistor 812, the second transistor 813, the third transistor 814, the fourth transistor 815, the fifth transistor 816, and the sixth transistor 817 for PWM.

According to an embodiment, a processor (e.g., the processor 535 of FIG. 5C) of a driving module (e.g., the driving module 530 of FIG. 5C) may control operations of the first transistor 812, the second transistor 813, the third transistor 814, the fourth transistor 815, the fifth transistor 816, and the sixth transistor 817 so that the motor 800 may be controlled based on PWM.

A shaft (or a camshaft) of the motor 800 may rotate based on currents applied to the U-phase coil 802, the V-phase coil 804, and the W-phase coil 806. For example, when a shaft of the motor 800 rotates, a magnet connected, directly or indirectly, to the shaft may also rotate. According to an embodiment, a current sensor (e.g., the current sensor 537 of FIG. 5C) may measure currents applied to the U-phase coil 802, the V-phase coil 804, and the W-phase coil 806.

According to an embodiment, the motor 800 may include a plurality of Hall sensors that may sense a position of the magnet. For example, when an N pole of the magnet is near a Hall sensor, the Hall sensor may output “1” as a sensing value. When an S pole of the magnet is near the Hall sensor, the Hall sensor may output “0” as a sensing value. For example, when half of a donut-shaped magnet rotating about a fixed position of the Hall sensor is an N pole and when the other half is an S pole, a period between a time at which the sensing value of the Hall sensor for the donut-shaped magnet changes from “0” to “1” and a time at which the sensing value changes from “1” to “0” may correspond to a period during which the magnet rotates 180°. When a plurality of Hall sensors is used, a rotation angle of the magnet may be determined. When the number of Hall sensors arranged around the magnet increases, an accuracy of the determined rotation angle may increase.

Since the magnet rotates together with the shaft of the motor 800, the determined rotation angle of the magnet may correspond to a rotation angle of the shaft of the motor 800. The rotation angle of the shaft of the motor 800 may be used to control a torque output through the motor 800. For example, when the shaft of the motor 800 needs to rotate “30” times to adjust a rotation angle of a leg support frame by 30°, the motor 800 may be controlled such that the shaft of the motor 800 may rotate “30” times by determining the rotation angle of the shaft of the motor 800. For example, the currents applied to the U-phase coil 802, the V-phase coil 804, and the W-phase coil 806 of the motor 800 may be controlled such that the shaft of the motor 800 may rotate “30” times.

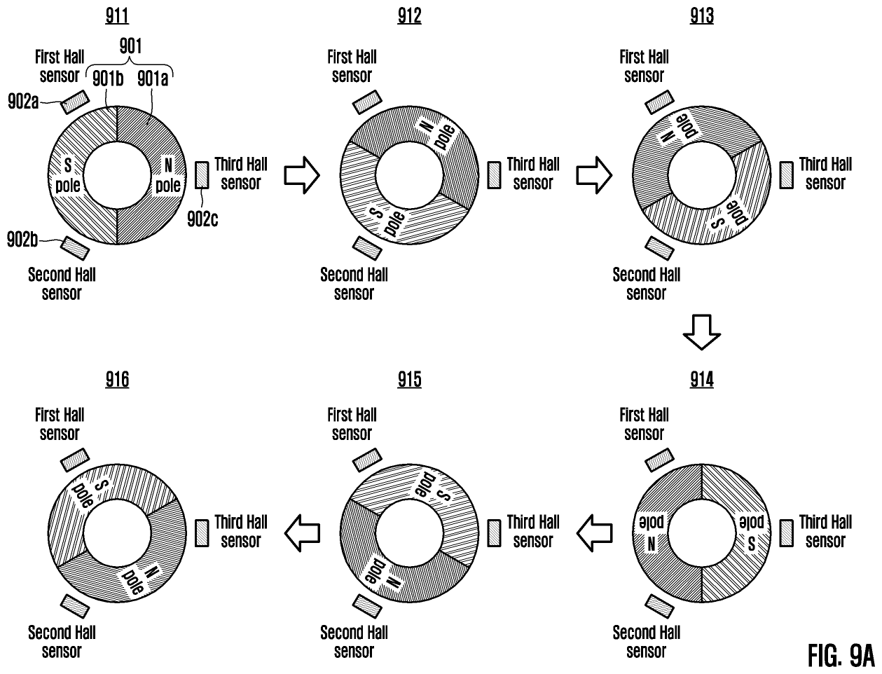

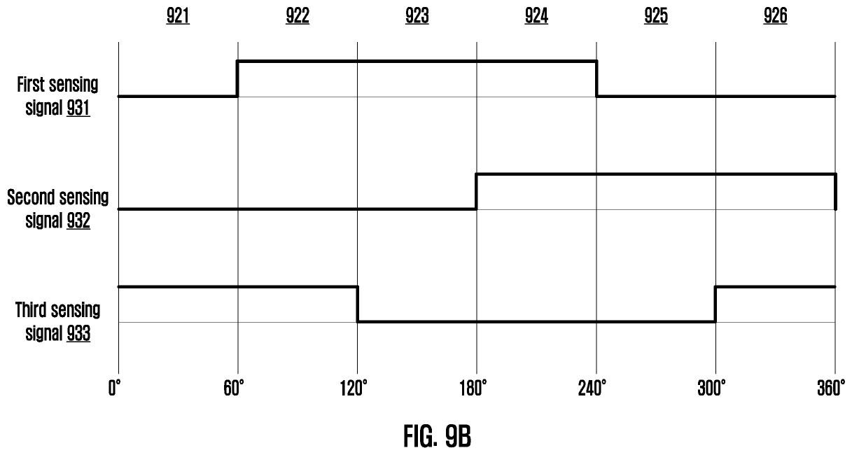

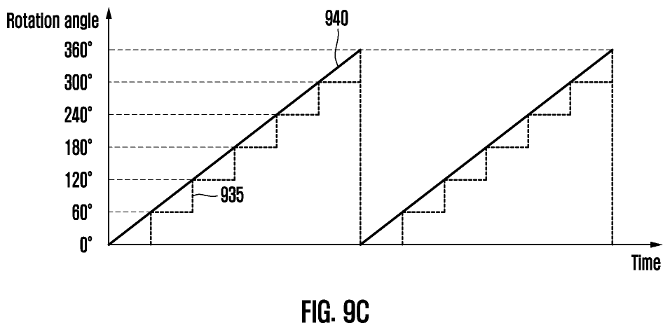

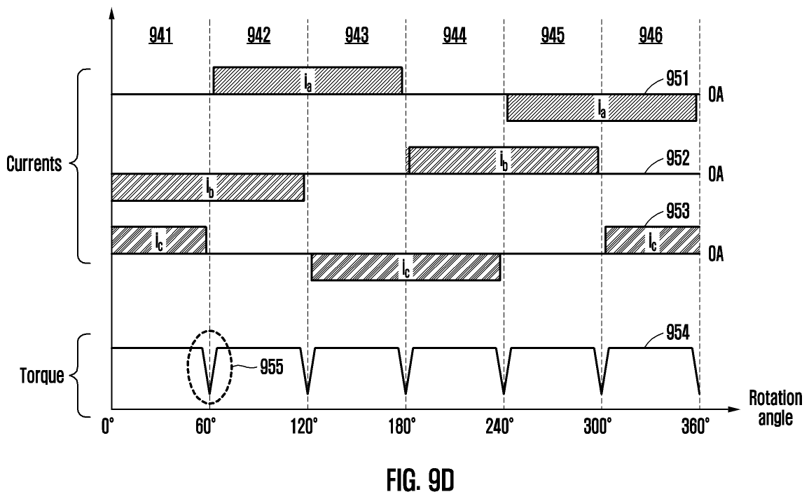

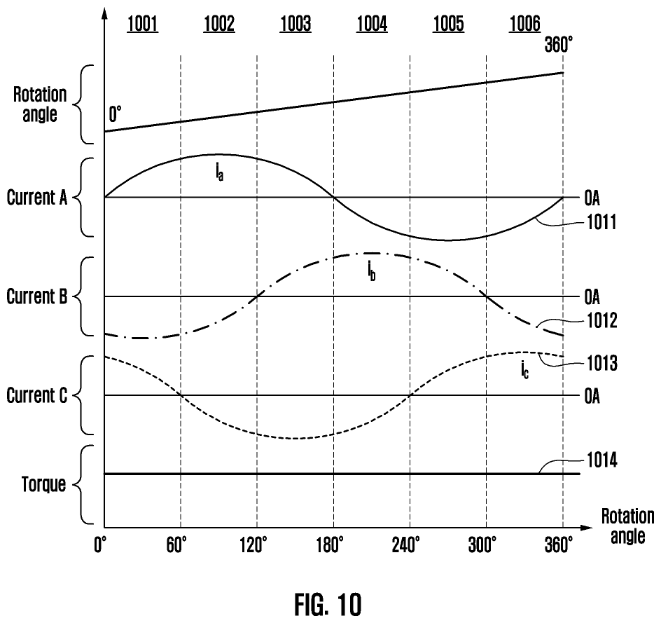

Hereinafter, a method of determining the rotation angle of the shaft of the motor 800 is described in detail with reference to FIGS. 9A, 9B, 9C, 9D, and 10.

FIG. 9A illustrates a magnet with a changing rotation angle and a plurality of Hall sensors arranged around the magnet, according to an embodiment.

In an embodiment, a motor (e.g., the motor 534 of FIG. 5A or the motor 800 of FIG. 8) may include a magnet 901. For example, when a shaft (or a camshaft) of the motor rotates, the magnet 901 may be disposed within the motor to rotate together with the shaft. For example, the magnet 901 may include an N pole 901a and an S pole 901b.

According to an embodiment, the motor may include a plurality of Hall sensors. For example, the plurality of Hall sensors may include a first Hall sensor 902a, a second Hall sensor 902b, and a third Hall sensor 902c. The first Hall sensor 902a (or the second Hall sensor 902b or the third Hall sensor 902c) may output “1” as a sensing value when the N pole 901a of the magnet 901 is disposed near the first Hall sensor 902a at a first point in time, and may output “O” as a sensing value when the S pole 901b of the magnet 910 is disposed near the first Hall sensor 902a. The first Hall sensor 902a may generate sensing values sensed over time as a first sensing signal.

When one half of the magnet 910 is the N pole 901a, when the other half is the S pole 901b, and when the first Hall sensor 902a, the second Hall sensor 902b, and the third Hall sensor 902c are arranged at 120° from the center of the magnet 910, six rotation states of the magnet 901 may be set.

For example, in a first rotation state 911 of the magnet 901, the first Hall sensor 902a and the second Hall sensor 902b may be disposed near the S pole 901b, and the third Hall sensor 902c may be disposed near the N pole 901a. The first Hall sensor 902a and the second Hall sensor 902b may generate “0” as a sensing value, and the third Hall sensor 902c may generate “1” as a sensing value.

For example, in a second rotation state 912 of the magnet 901, the first Hall sensor 902a and the third Hall sensor 902c may be disposed near the N pole 901a, and the second Hall sensor 902b may be disposed near the S pole 901b. The first Hall sensor 902a and the third Hall sensor 902c may generate “1” as sensing values, and the second Hall sensor 902b may generate “O” as a sensing value.

For example, in a third rotation state 913 of the magnet 901, the first Hall sensor 902a may be disposed near the N pole 901a, and the second Hall sensor 902b and the third Hall sensor 902c may be disposed near the S pole 901b. The first Hall sensor 902a may generate “1” as a sensing value, and the second Hall sensor 902b and the third Hall sensor 902c may generate “0” as sensing values.

For example, in a fourth rotation state 914 of the magnet 901, the first Hall sensor 902a and the second Hall sensor 902b may be disposed near the N pole 901a, and the third Hall sensor 902c may be disposed near the S pole 901b. The first Hall sensor 902a and the second Hall sensor 902b may generate “1” as sensing values, and the third Hall sensor 902c may generate “0” as a sensing value.

For example, in a fifth rotation state 915 of the magnet 901, the first Hall sensor 902a and the third Hall sensor 902c may be disposed near the S pole 901b, and the second Hall sensor 902b may be disposed near the N pole 901a. The first Hall sensor 902a and the third Hall sensor 902c may generate “0” as sensing values, and the second Hall sensor 902b may generate “1” as a sensing value.

For example, in a sixth rotation state 916 of the magnet 901, the first Hall sensor 902a may be disposed near the S pole 901b, and the second Hall sensor 902b and the third Hall sensor 902c may be disposed near the N pole 901a. The first Hall sensor 902a may generate “O” as a sensing value, and the second Hall sensor 902b and the third Hall sensor 902c may generate “1” as sensing values.

FIG. 9B illustrates a plurality of sensing signals of a plurality of Hall sensors sensed for a rotation of a magnet, according to an embodiment.

While the magnet 901 described above with reference to FIG. 9A rotates once, the first Hall sensor 902a may generate a first sensing signal 931, the second Hall sensor 902b may generate a second sensing signal 932, and the third Hall sensor 902c may generate a third sensing signal 933.

According to an embodiment, one rotation of the magnet 901 may be divided into six sections.

A first section 921 may be a section in which a value of the first sensing signal and a value of the second sensing signal are “0” (or a low signal) and a value of the third sensing signal is “1” (or a high signal). The rotation angle of the shaft of the motor at the start of the first section 921 may be defined as 0°. The first rotation state 911 of the magnet 901 described above with reference to FIG. 9A may correspond to the first section 921.

A second section 922 may be a section in which the value of the first sensing signal and the value of the third sensing signal are “1” (or a high signal) and the value of the second sensing signal is “0” (or a low signal). The rotation angle of the shaft of the motor at the start of the second section 922 may be defined as 60°. The second rotation state 912 of the magnet 901 described above with reference to FIG. 9A may correspond to the second section 922.

The third section 923 may be a section in which the value of the first sensing signal is “1” (or a high signal) and the value of the second sensing signal and the value of the third sensing signal are “0” (or a low signal). The rotation angle of the shaft of the motor at the start of the third section 923 may be defined as 120°. The third rotation state 913 of the magnet 901 described above with reference to FIG. 9A may correspond to the third section 923.

The fourth section 924 may be a section in which the value of the first sensing signal and the value of the second sensing signal are “1” (or a high signal) and the value of the third sensing signal is “0” (or a low signal). The rotation angle of the shaft of the motor at the start of the fourth section 924 may be defined as 180°. The fourth rotation state 914 of the magnet 901 described above with reference to FIG. 9A may correspond to the fourth section 924.

The fifth section 925 may be a section in which the value of the first sensing signal and the value of the third sensing signal are “0” (or a low signal) and the value of the second sensing signal is “1” (or a high signal). The rotation angle of the shaft of the motor at the start of the fifth section 925 may be defined as 240°. The fifth rotation state 915 of the magnet 901 described above with reference to FIG. 9A may correspond to the fifth section 925.

The sixth section 926 may be a section in which the value of the first sensing signal is “0” (or a low signal) and the value of the second sensing signal and the value of the third sensing signal are “1” (or a high signal). The rotation angle of the shaft of the motor at the start of the sixth section 926 may be defined as 300°. The sixth rotation state 916 of the magnet 901 described above with reference to FIG. 9A may correspond to the sixth section 926.

FIG. 9C illustrates a first rotation angle trajectory of a magnet determined based on a plurality of sensing signals of a plurality of Hall sensors and a linear second rotation angle trajectory determined based on the first rotation angle trajectory, according to an embodiment.

According to an embodiment, while a magnet (e.g., the magnet 901 of FIG. 9A) rotates twice, a first rotation angle trajectory 935 may be determined based on a plurality of sensing signals (e.g., the first sensing signal 931, the second sensing signal 932, and the third sensing signal 933 of FIG. 9B) generated by a plurality of Hall sensors (e.g., the first Hall sensor 902a, the second Hall sensor 902b, and the third Hall sensor 902c of FIG. 9A).

According to an embodiment, a linear second rotation angle trajectory 940 may be determined based on the first rotation angle trajectory 935. For example, the second rotation angle trajectory 940 may be determined based on an integral value of the first rotation angle trajectory 935 and a rotation speed of the shaft of the motor (e.g., the motor 534 of FIG. 5A or the motor 800 of FIG. 8). The second rotation angle trajectory 940 may correspond to a rotation angle trajectory of the shaft of the motor generated by a resolver or an encoder.

The first rotation angle trajectory 935 may need to be accurately generated so that the second rotation angle trajectory 940 may exactly correspond to a rotation angle of a shaft of an actual motor. For example, when a section start rotation angle corresponding to each of six sections defined by the plurality of sensing signals generated by the plurality of Hall sensors is different from an actual rotation angle, the first rotation angle trajectory 935 and the second rotation angle trajectory 940 may not temporarily correspond. When the first rotation angle trajectory 935 and the second rotation angle trajectory 940 do not temporarily correspond, a control of the motor may be unstable, and a ripple may occur in the torque output by the motor due to the unstable control of the motor.

FIG. 9D illustrates a torque trajectory that appears as currents applied to a motor are controlled in six steps, according to an embodiment.

According to an embodiment, a driving module (e.g., the driving module 530 of FIG. 5C) may include at least one processor (e.g., the processor 535 of FIG. 5C) and memory (e.g., the memory 536 of FIG. 5C) storing instructions executable by the at least one processor. The instructions, when executed by the at least one processor, may cause the driving module to determine a state of a motor (e.g., the motor 534 of FIG. 5A or the motor 800 of FIG. 8). The driving module may further include a motor and a current sensor (e.g., the current sensor 537 of FIG. 5C). For example, the current sensor may sense a value of a current flowing in each of coils of the motor.

According to an embodiment, the driving module may independently operate to determine a state of the motor when power is supplied to the driving module, even when the driving module is not installed in a wearable device (e.g., the wearable device 100 of FIG. 1).

For example, the driving module may control the motor by controlling currents applied to three-phase coils (e.g., the U-phase coil 802, the V-phase coil 804, and the W-phase coil 806 of FIG. 8) of the motor (e.g., the motor 534 of FIG. 5A or the motor 800 of FIG. 8) to output torque through the motor.

The driving module may determine a target section corresponding to a current rotation angle of a shaft of the motor among six sections (e.g., sections 941, 942, 943, 944, 945, and 946) based on a plurality of sensing signals (e.g., the first sensing signal 931, the second sensing signal 932, and the third sensing signal 933 of FIG. 9B) generated by a plurality of Hall sensors (e.g., the first Hall sensor 902a, the second Hall sensor 902b, and the third Hall sensor 902c of FIG. 9A), and may apply currents corresponding to the target section to the three-phase coils. For example, a first current trajectory 951 may be a trajectory of a current applied to the U-phase coil 802, a second current trajectory 952 may be a trajectory of a current applied to the V-phase coil 804, and a third current trajectory 953 may be a trajectory of a current applied to the W-phase coil 806. A torque trajectory 954 may be a trajectory of a torque output by the motor by currents applied to the motor.

A current having a positive value of the first current trajectory 951 may appear when the first transistor 812 is powered on, and a current having a negative value of the first current trajectory 951 may appear when the fourth transistor 815 is powered on. A current having a positive value of the second current trajectory 952 may appear when the second transistor 813 is powered on, and a current having a negative value of the second current trajectory 952 may appear when the fifth transistor 816 is powered on. A current having a positive value of the third current trajectory 953 may appear when the third transistor 814 is powered on, and a current having a negative value of the third current trajectory 953 may appear when the sixth transistor 817 is powered on.

When the target section is the section 941, the current having the negative value of the second current trajectory 952 and the current having the positive value of the third current trajectory 953 may be applied to the motor. The shaft of the motor may rotate based on the applied currents and a torque may be generated by the rotation of the shaft. When the target section changes from the section 941 to the section 942, the currents applied to the motor may change. For example, the current having the negative value of the second current trajectory 952 may continue to be applied to the motor, however, the applying of the current having the positive value of the third current trajectory 953 may be stopped, and applying of the current having the positive value of the first current trajectory 951 may be started. A torque ripple 955 may occur as the currents applied to the motor change. If the torque ripple 955 occurs, the motor may vibrate, and noise may also occur due to the vibration of the motor.

FIG. 10 illustrates a torque trajectory that appears as currents applied to a motor are controlled by field-oriented control (FOC), according to an embodiment.

According to an embodiment, when a rotation angle of a shaft of a motor (e.g., the motor 534 of FIG. 5A or the motor 800 of FIG. 8) is linearly determined, the driving module described above with reference to FIG. 9A to 9D may output a torque through the motor by applying currents corresponding to a current rotation angle to the motor through the FOC.

The driving module may determine a current rotation angle of the shaft of the motor based on a plurality of sensing signals (e.g., the first sensing signal 931, the second sensing signal 932, and the third sensing signal 933 of FIG. 9B) generated by a plurality of Hall sensors (e.g., the first Hall sensor 902a, the second Hall sensor 902b, and the third Hall sensor 902c of FIG. 9A). For example, the driving module may determine a target section corresponding to the plurality of sensing signals among six sections (e.g., sections 1001, 1002, 1003, 1004, 1005, and 1006) and determine the current rotation angle based on an integral value of a section start rotation angle of the target section and a rotation speed of the shaft of the motor. The driving module may apply currents corresponding to the current rotation angle to three-phase coils (e.g., the U-phase coil 802, the V-phase coil 804, and the W-phase coil 806 of FIG. 8). For example, a first current trajectory 1011 may be a trajectory of a current applied to the U-phase coil 802, a second current trajectory 1012 may be a trajectory of a current applied to the V-phase coil 804, and a third current trajectory 1013 may be a trajectory of a current applied to the W-phase coil 806. A torque trajectory 1014 may be a trajectory of a torque output by the motor by currents applied to the motor. Since the current rotation angle determined during the rotation of the shaft of the motor linearly changes, a torque of the motor output based on the current rotation angle may be stable without ripple.

In a method of controlling currents applied to the motor by the FOC, to stabilize the output torque, the current rotation angle determined during the rotation of the shaft of the motor may need to linearly change.

According to an embodiment, when Hall sensors are arranged within the motor correctly as designed, section start rotation angles predefined for each of the six sections (e.g., the sections 1001, 1002, 1003, 1004, 1005, and 1006) may be identical to actual sensing values.

According to an embodiment, when the Hall sensors are arranged within the motor incorrectly unlike that designed, the section start rotation angles predefined for each of the six sections (e.g., the sections 1001, 1002, 1003, 1004, 1005, and 1006) may differ from the actual sensing values.

Hereinafter, a method of determining a state of a motor in association with an arrangement of Hall sensors is described in detail with reference to FIGS. 11 to 23.

FIG. 11 is a flowchart of a method of determining a state of a motor, according to an embodiment.

Operations 1110 to 1130 of FIG. 11 may be performed by a driving module (e.g., the driving module 530 of FIG. 5C). The driving module may include a processor (e.g., the processor 535 of FIG. 5C) and memory (e.g., the memory 536 of FIG. 5C). The memory may store instructions executable by the processor.

In operation 1110, the driving module may control a motor (e.g., the motor 534 of FIG. 5A or the motor 800 of FIG. 8) of the driving module such that a shaft (or a camshaft) of the motor may rotate at a target speed. For example, the shaft of the motor may not be connected to a load. The driving module may control the motor such that the shaft of the motor under a no-load state may rotate at the target speed. The speed may be an angular velocity.

According to an embodiment, the driving module may control a motor driver circuit (e.g., the motor driver circuit 532 of FIG. 5A or the motor driver circuit 810 of FIG. 8) connected, directly or indirectly, to the motor, using FOC, to control the motor such that the shaft of the motor may rotate at the target speed. For example, the driving module may apply currents, applied to three-phase coils of the motor, to the motor driver circuit through FOC, such that the shaft of the motor may rotate at the target speed. For example, the driving module may apply currents, applied to the three-phase coils of the motor, to the motor driver circuit, using the first current trajectory 1011, the second current trajectory 1012, and the third current trajectory 1013 described above with reference to FIG. 10.

In operation 1120, the driving module may receive a first sensing signal (e.g., the first sensing signal 931 of FIG. 9B) from a first Hall sensor (e.g., the first Hall sensor 902a of FIG. 9A) configured to sense a rotation angle of the shaft of the motor, and may receive a second sensing signal (e.g., the second sensing signal 932 of FIG. 9B) from a second Hall sensor (e.g., the second Hall sensor 902b of FIG. 9A), while the shaft of the motor rotates at the target speed. The driving module may further receive a third sensing signal (e.g., the third sensing signal 933 of FIG. 9B) from a third Hall sensor (e.g., the third Hall sensor 902c of FIG. 9A).

In operation 1130, the driving module may determine whether the first Hall sensor and the second Hall sensor are arranged normally within the motor based on the first sensing signal and the second sensing signal. When the third sensing signal is further received, the driving module may determine whether the first Hall sensor, the second Hall sensor, and the third Hall sensor are arranged normally within the motor based on the first sensing signal, the second sensing signal, and the third sensing signal.

When the shaft of the motor rotates at the constant target speed, a first actual time of a first section in which the rotation angle of the shaft changes from 0° to 60°, a second actual time of a second section in which the rotation angle changes from 60° to 120°, a third actual time of a third section in which the rotation angle changes from 120° to 180°, a fourth actual time of a fourth section in which the rotation angle changes from 180° to 240°, a fifth actual time of a fifth section in which the rotation angle changes from 240° to 300°, and a sixth actual time of a sixth section in which the rotation angle changes from 300° to 360° may be identical to each other.

When a plurality of Hall sensors including a first Hall sensor and a second Hall sensor is arranged within the motor correctly as designed, a first measurement time of the first section, a second measurement time of the second section, a third measurement time of the third section, a fourth measurement time of the fourth section, a fifth measurement time of the fifth section, and a sixth measurement time of the sixth section, which are distinguished by a plurality of sensing signals may be identical to the first actual time, the second actual time, the third actual time, the fourth actual time, the fifth actual time, and the sixth actual time, respectively.

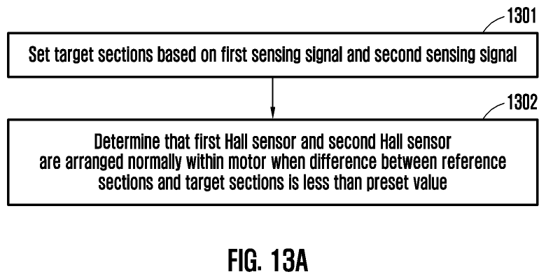

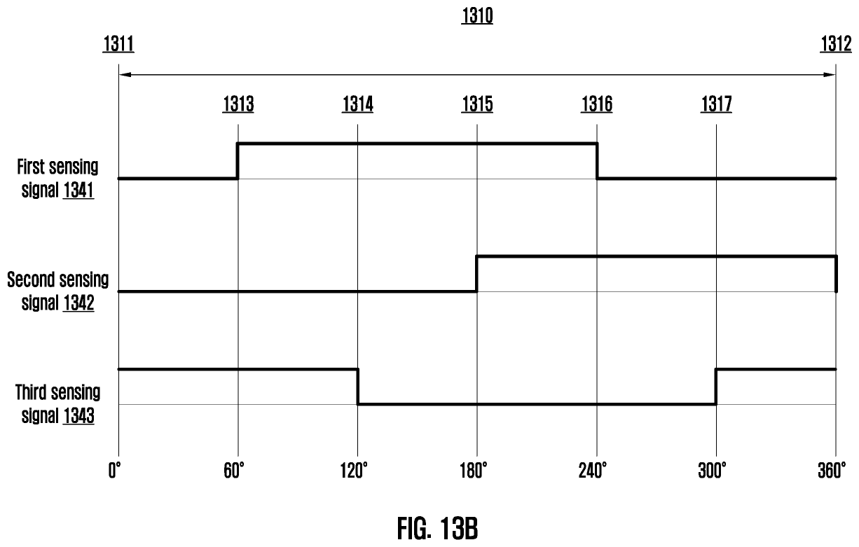

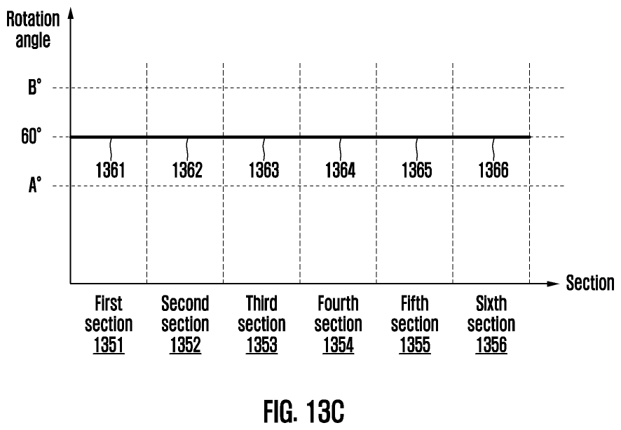

According to an embodiment, when the first measurement time, the second measurement time, the third measurement time, the fourth measurement time, the fifth measurement time, and the sixth measurement time are identical or correspond to the first actual time, the second actual time, the third actual time, the fourth actual time, the fifth actual time, and the sixth actual time, respectively, the driving module may determine that the first Hall sensor and the second Hall sensor are arranged normally within the motor. For example, when a difference between the second measurement time and the second actual time is less than a preset threshold time, the second measurement time and the second actual time may be determined to correspond. Hereinafter, a method of determining that the first Hall sensor and the second Hall sensor are arranged normally within the motor is described in detail with reference to FIGS. 13A, 13B, and 13C.

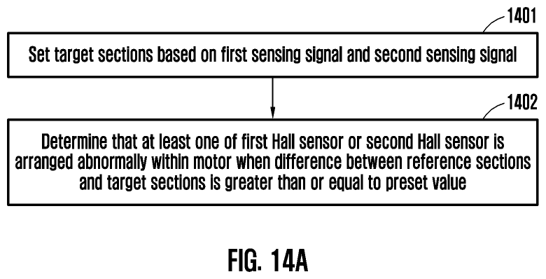

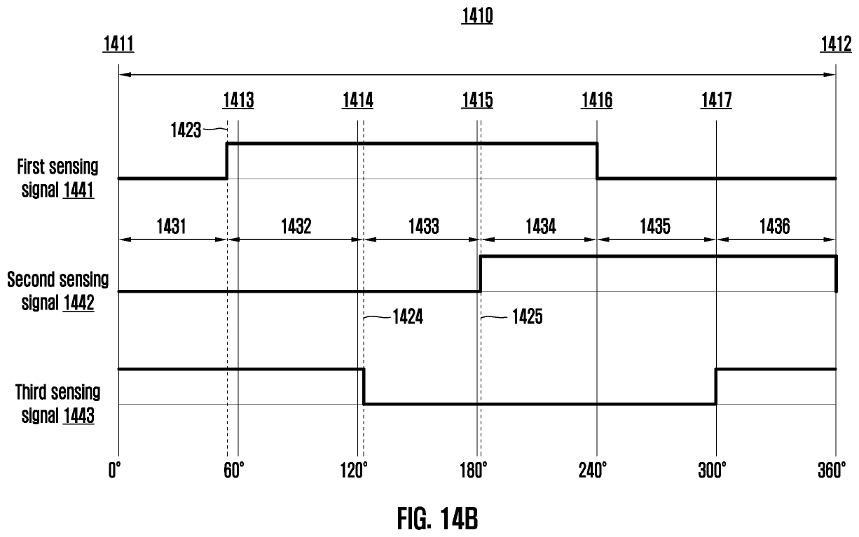

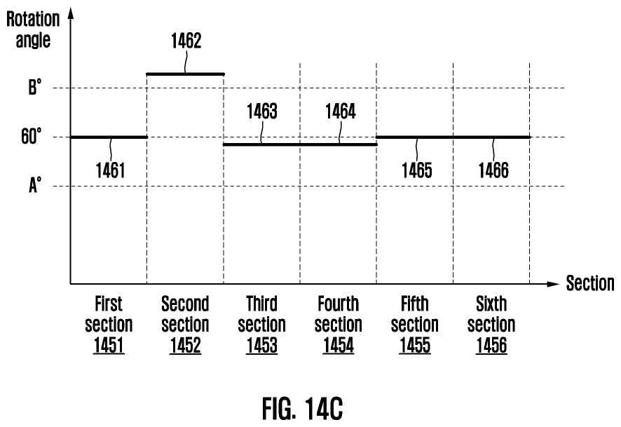

According to an embodiment, when at least one of the first measurement time, the second measurement time, the third measurement time, the fourth measurement time, the fifth measurement time, or the sixth measurement time does not correspond to each of the first actual time, the second actual time, the third actual time, the fourth actual time, the fifth actual time, and the sixth actual time, the driving module may determine that at least one of the first Hall sensor or the second Hall sensor is arranged abnormally within the motor. For example, when the difference between the second measurement time and the second actual time is greater than or equal to the preset threshold time, it may be determined that the second measurement time and the second actual time do not correspond. Hereinafter, a method of determining that the first Hall sensor and the second Hall sensor are arranged abnormally within the motor is described in detail with reference to FIGS. 14A, 14B, and 14C.

According to an embodiment, when at least one of the first Hall sensor or the second Hall sensor is determined to be arranged abnormally within the motor, the driving module may calibrate or adjust sections of a rotation angle distinguished by the first Hall sensor and the second Hall sensor. For example, when a first section of 0° to 60°, a second section of 60° to 120°, a third section of 120° to 180°, a fourth section of 180° to 240°, a fifth section of 240° to 300°, and a sixth section of 300° to 360° are defined as basic sections, a start rotation angle for at least one of the first section to the sixth section may be calibrated based on the first sensing signal and the second sensing signal. For example, when the second measurement time is greater than the second actual time and when the third measurement time is less than the third actual time, a start rotation angle of the third section may be adjusted from 120° to 110°. As the start rotation angle of the third section is adjusted from 120° to 110°, an end rotation angle of the second section may be adjusted from 120° to 110°. The processor of the driving module may store information on the calibrated sections of the rotation angle distinguished by the first Hall sensor and the second Hall sensor.

Hereinafter, a method of calibrating sections of a rotation angle distinguished by the first Hall sensor and the second Hall sensor when it is determined that the first Hall sensor and the second Hall sensor are arranged abnormally within the motor is described in detail with reference to FIGS. 14A, 14B, and 14C.

According to an embodiment, the driving module may re-perform operations 1110 to 1130 after calibrating the sections of the rotation angle distinguished by the first Hall sensor and the second Hall sensor. For example, unlike operation 1130 that is initially performed, the first actual time of the first section in which the rotation angle of the shaft changes from 0° to 60°, the second actual time of the second section in which the rotation angle changes from 60° to 110°, the third actual time of the third section in which the rotation angle changes from 110° to 180°, the fourth actual time of the fourth section in which the rotation angle changes from 180° to 240°, the fifth actual time of the fifth section in which the rotation angle changes from 240° to 300°, and the sixth actual time of the sixth section in which the rotation angle changes from 300° to 360° may be compared to the first measurement time of the first section, the second measurement time of the second section, the third measurement time of the third section, the fourth measurement time of the fourth section, the fifth measurement time of the fifth section, and the sixth measurement time of the sixth section, which are distinguished by the plurality of sensing signals.

When the first measurement time, the second measurement time, the third measurement time, the fourth measurement time, the fifth measurement time, and the sixth measurement time are identical or correspond to the first actual time, the second actual time, the third actual time, the fourth actual time, the fifth actual time, and the sixth actual time, respectively, the driving module may determine that the first Hall sensor and the second Hall sensor are arranged normally within the motor.

When at least one of the first measurement time, the second measurement time, the third measurement time, the fourth measurement time, the fifth measurement time, or the sixth measurement time does not correspond to each of the first actual time, the second actual time, the third actual time, the fourth actual time, the fifth actual time, and the sixth actual time, the driving module may determine that at least one of the first Hall sensor or the second Hall sensor is arranged abnormally within the motor.

According to an embodiment, start rotation angles for each of the sections of the rotation angle of the shaft of the motor may be used to determine a current angle of the shaft of the motor. For example, when the motor is mounted in a driving module (e.g., the driving module 120 of FIG. 1 or the driving module 35, 45 of FIG. 3) of a wearable device, the start rotation angles for each of the sections of the rotation angle of the shaft of the motor may be used to determine a current angle of the motor for outputting a torque.

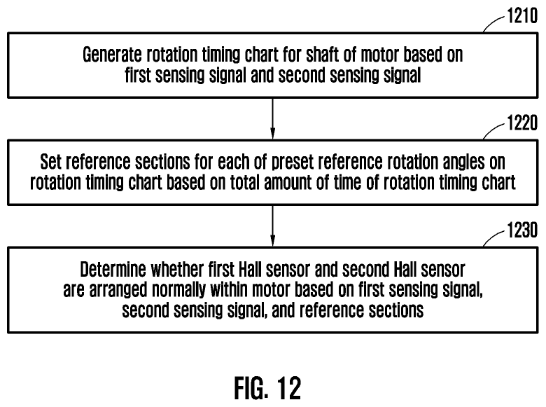

FIG. 12 is a flowchart of a method of determining whether Hall sensors are arranged normally within a motor based on a rotation timing chart for a shaft of the motor generated using sensing signals, according to an embodiment.

According to an embodiment, operations 1210 to 1230 of FIG. 12 may be related to operation 1130 described above with reference to FIG. 11. For example, operation 1130 may include operations 1210 to 1230.

Operations 1210 to 1230 may be performed by a driving module (e.g., the driving of FIG. 5C) and memory (e.g., the memory 536 of FIG. 5C). The memory may store instructions executable by the processor.

In operation 1210, the driving module may generate the rotation timing chart for the shaft of the motor based on a first sensing signal and a second sensing signal that are generated by a first Hall sensor (e.g., the first Hall sensor 902a of FIG. 9A) and a second Hall sensor (e.g., the second Hall sensor 902b of FIG. 9A), respectively. For example, the driving module may generate a rotation timing chart, further based on a third sensing signal generated by a third Hall sensor (e.g., the third Hall sensor 902c of FIG. 9A).

An x-axis of the rotation timing chart may correspond to the total amount of time for one rotation of the shaft of the motor. The first sensing signal and the second sensing signals may be arranged on a y-axis of the rotation timing chart. The rotation timing chart may show the first sensing signal and second sensing signals which change during one rotation of the shaft of the motor. The rotation timing chart is described in detail below with reference to FIGS. 13B and 14B.

In operation 1220, the driving module may set reference sections for each of preset reference rotation angles on the rotation timing chart based on the total amount of time of the rotation timing chart. For example, when the number of Hall sensors is three, six reference sections may be set. For example, the reference sections may include a first reference section of 0° to 60°, a second reference section of 60° to 120°, a third reference section of 120° to 180°, a fourth reference section of 180° to 240°, a fifth reference section of 240° to 300°, and a sixth reference section of 300° to 360°. For example, when the total amount of time of the rotation timing chart is 3.6 seconds, the reference sections may be set on the rotation timing chart such that a first time of the first reference section, a second time of the second reference section, a third time of the third reference section, a fourth time of the fourth reference section, a fifth time of the fifth reference section, and a sixth time of the sixth reference section may each be 0.6 seconds.

In operation 1230, the driving module may determine whether the first Hall sensor and the second Hall sensor are arranged normally within the motor based on the first sensing signal, the second sensing signal, and the reference sections. For example, whether the first Hall sensor and the second Hall sensor are arranged normally within the motor may be determined based on whether the target sections set based on the first sensing signal and the second sensing signal correspond to the reference sections. If the target sections correspond to the reference sections, the first Hall sensor and the second Hall sensor may be determined to be arranged normally within the motor.

Hereinafter, a method of determining that the first Hall sensor and the second Hall sensor are arranged normally within the motor is described in detail with reference to FIGS. 13A, 13B, and 13C.

Hereinafter, a method of determining that the first Hall sensor and the second Hall sensor are arranged abnormally within the motor is described in detail with reference to FIGS. 14A, 14B, and 14C.

FIG. 13A is a flowchart of a method of determining that Hall sensors are arranged normally within a motor based on a rotation timing chart for a shaft of the motor generated using sensing signals, according to an embodiment.

According to an embodiment, operations 1301 and 1302 of FIG. 13A may be related to operation 1230 described above with reference to FIG. 12. For example, operation 1230 may include operations 1301 and 1302.

Operations 1301 and 1302 may be performed by a driving module (e.g., the driving of FIG. 5C) and memory (e.g., the memory 536 of FIG. 5C). The memory may store instructions executable by the processor.

In operation 1301, the driving module may set target sections on the rotation timing chart based on a first sensing signal and a second sensing signal. For example, when a plurality of Hall sensors may include a first Hall sensor (e.g., the first Hall sensor 902a of FIG. 9A), a second Hall sensor (e.g., the second Hall sensor 902b of FIG. 9A), and a third Hall sensor (e.g., the third Hall sensor 902c of FIG. 9A), target sections may be set based on a first sensing signal (e.g., the first sensing signal 931 of FIG. 9B), a second sensing signal (e.g., the second sensing signal 932 of FIG. 9B), and a third sensing signal (e.g., the third sensing signal 933 of FIG. 9B).

According to an embodiment, a time at which one of a value of the first sensing signal, a value of the second sensing signal, and a value of the third sensing signal changes to another value may be determined as a start of a next target section. For example, six target sections may be set on the rotation timing chart based on the first sensing signal, the second sensing signal, and the third sensing signal.

In operation 1302, the driving module may determine that the first Hall sensor and the second Hall sensor are arranged normally within the motor when a difference between the reference sections and the target sections is less than a preset value. For example, if the second reference section corresponds to 0.6 seconds and if a second target section corresponds to 0.63 seconds, 0.03 seconds may be determined as a difference between the second reference section and the second target section. When differences between each of the other reference sections and the second target section, including 0.03 seconds, are less than a preset value, the first Hall sensor and the second Hall sensor may be determined to be arranged normally within the motor.

According to an embodiment, when the difference between the reference sections and the target sections is less than the preset value, the driving module may calibrate or adjust sections of the rotation angle distinguished by Hall sensors by setting target rotation angles for each of the reference sections.

FIG. 13B illustrates a rotation timing chart for a shaft of a motor generated using sensing signals, according to an embodiment.

According to an embodiment, a rotation timing chart 1310 for a shaft of a motor (e.g., the motor 534 of FIG. 5A or the motor 800 of FIG. 8) may be generated based on a first sensing signal 1341, a second sensing signal 1342, and a third sensing signal 1343 that are received from a first Hall sensor (e.g., the first Hall sensor 902a of FIG. 9A), a second Hall sensor (e.g., the second Hall sensor 902b of FIG. 9A), and a third Hall sensor (e.g., the third Hall sensor 902c of FIG. 9A), respectively. For example, the rotation timing chart 1310 may be generated based on an average value of a plurality of rotations.

The total amount of time for one rotation of the rotation timing chart 1310 may be a period from a start time 1311 to an end time 1312. Based on the total amount of time of the rotation timing chart 1310, reference sections may be set for each of preset reference rotation angles on the rotation timing chart 1310. The reference rotation angles may be 0°, 60°, 120°, 180°, 240°, and 300°. For example, if the total amount of time is 3.6 seconds, each of the reference sections may be set to 0.6 seconds, which is ⅙ of the total amount of time. For example, a first reference section may correspond to a period from the start time 1311 to a time 1313, a second reference section may correspond to a period from the time 1313 to a time 1314, a third reference section may correspond to a period from the time 1314 to a time 1315, a fourth reference section may correspond to a period from the time 1315 to a time 1316, a fifth reference section may correspond to a period from the time 1316 to a time 1317, and a sixth reference section may correspond to a period from the time 1317 to the end time 1312.

Target sections may be set on the rotation timing chart 1310 based on the first sensing signal 1341, the second sensing signal 1342, and the third sensing signal 1343. A time at which one of a value of the first sensing signal 1341, a value of the second sensing signal 1342, and a value of the third sensing signal 1343 changes to another value may be determined as a start of a next target section. For example, six target sections may be set on the rotation timing chart 1310 based on the first sensing signal 1341, the second sensing signal 1342, and the third sensing signal 1343. For example, the first target section may be a section in which the value of the first sensing signal 1341 is “0” (or a low signal), in which the value of the second sensing signal 1342 is “0,” and in which the value of the third sensing signal 1343 is “1” (or a high signal). For example, the second target section may be a section in which the value of the first sensing signal 1341 and the value of the third sensing signal 1343 are “1” and in which the value of the second sensing signal 1342 is “0.” For example, the third target section may be a section in which the value of the first sensing signal 1341 is “1,” and in which the value of the second sensing signal 1342 and the value of the third sensing signal 1343 are “0.” For example, the fourth target section may be a section in which the value of the first sensing signal 1341 and the value of the second sensing signal 1342 are “1” and in which the value of the third sensing signal 1343 is “0.” For example, the fifth target section may be a section in which the value of the first sensing signal 1341 and the value of the third sensing signal 1343 are “0” and in which the value of the second sensing signal 1342 is “1.” For example, the sixth target section may be a section in which the value of the first sensing signal 1341 is “0,” and in which the value of the second sensing signal 1342 and the value of the third sensing signal 1343 are “1”

When the first Hall sensor, the second Hall sensor, and the third Hall sensor are arranged within the motor correctly as designed, the target sections may match the reference sections.

FIG. 13C illustrates rotation angles of a shaft of a motor for each section, according to an embodiment.

According to an embodiment, rotation angles may be determined for each of a first target section 1351 to a sixth target section 1356. The first target section 1351 to the sixth target section 1356 may correspond to the target sections described above with reference to FIG. 13B. For example, a first rotation angle 1361 for the first target section 1351 may be determined based on a ratio of a period of the first target section 1351 to the total amount of time. For example, when the total amount of time is 3.6 seconds and when the period of the first target section 1351 is 0.6 seconds, the first rotation angle 1361 for the first target section 1351 may be determined as 60°. Similarly, when a period of each of the second target section 1352 to the sixth target section 1356 is 0.6 seconds, each of rotation angles 1362 to 1366 for the second target section 1352 to the sixth target section 1356 may be determined as 60°.

According to an embodiment, when the determined rotation angles are all within a preset range (e.g., a range of A° to) B°, the first Hall sensor, the second Hall sensor, and the third Hall sensor may be determined to be arranged normally within the motor.

FIG. 14A is a flowchart of a method of determining that Hall sensors are arranged abnormally within a motor based on a rotation timing chart for a shaft of the motor generated using sensing signals, according to an embodiment.

According to an embodiment, operations 1401 and 1402 below may be related to operation 1230 described above with reference to FIG. 12. For example, operation 1230 may include operations 1401 and 1402.

Operations 1401 and 1402 may be performed by a driving module (e.g., the driving of FIG. 5C) and memory (e.g., the memory 536 of FIG. 5C). The memory may store instructions executable by the processor.

In operation 1401, the driving module may set target sections on a rotation timing chart based on a first sensing signal and a second sensing signal. The description of operation 1401 may be replaced with the description of operation 1301 described above with reference to FIG. 13A.

In operation 1402, the driving module may determine that at least one of the first Hall sensor or the second Hall sensor is arranged abnormally within the motor when a difference between reference sections and the target sections is greater than or equal to a preset value. For example, if the second reference section corresponds to 0.6 seconds and if a second target section corresponds to 0.63 seconds, 0.03 seconds may be determined as a difference between the second reference section and the second target section. When at least one of differences between each of the other reference sections and the second target section, including 0.03 seconds, is greater than a preset value, the first Hall sensor and the second Hall sensor may be determined to be arranged abnormally within the motor.

According to an embodiment, when the difference between the reference sections and the target sections is greater than or equal to the preset value, the driving module may calibrate or adjust sections of the rotation angle distinguished by Hall sensors by setting target rotation angles for each of the reference sections.

FIG. 14B illustrates a rotation timing chart for a shaft of a motor generated using sensing signals, according to an embodiment.

According to an embodiment, a rotation timing chart 1410 for a shaft of a motor (e.g., the motor 534 of FIG. 5A or the motor 800 of FIG. 8) may be generated based on a first sensing signal 1441, a second sensing signal 1442, and a third sensing signal 1443 that are received from a first Hall sensor (e.g., the first Hall sensor 902a of FIG. 9A), a second Hall sensor (e.g., the second Hall sensor 902b of FIG. 9A), and a third Hall sensor (e.g., the third Hall sensor 902c of FIG. 9A), respectively. For example, the rotation timing chart 1410 may be generated based on an average value for a plurality of rotations.

The total amount of time for one rotation of the rotation timing chart 1410 may be a period from a start time 1411 to an end time 1412. Based on the total amount of time of the rotation timing chart 1410, reference sections may be set for each of preset reference rotation angles on the rotation timing chart 1410. The reference rotation angles may be 0°, 60°, 120°, 180°, 240°, and 300°. For example, if the total amount of time is 3.6 seconds, each of the reference sections may be set to 0.6 seconds, which is ⅙ of the total amount of time. For example, a first reference section may correspond to a period from the start time 1411 to a time 1413, a second reference section may correspond to a period from the time 1413 to a time 1414, a third reference section may correspond to a period from the time 1414 to a time 1415, a fourth reference section may correspond to a period from the time 1415 to a time 1416, a fifth reference section may correspond to a period from the time 1416 to a time 1417, and a sixth reference section may correspond to a period from the time 1417 to the end time 1412.

Target sections may be set on the rotation timing chart 1410 based on the first sensing signal 1441, the second sensing signal 1442, and the third sensing signal 1443. A time at which one of a value of the first sensing signal 1441, a value of the second sensing signal 1442, and a value of the third sensing signal 1443 changes to another value may be determined as a start of a next target section. For example, a first target section 1431 may be set based on a time 1423 at which the value of the first sensing signal 1441 changes from “0” to “1,” a second target section 1432 may be set based on a time 1424 at which the value of the third sensing signal 1443 changes from “1” to “0,” a third target section 1433 may be set based on a time 1425 at which the value of the second sensing signal 1442 changes from “0” to “1,” a fourth target section 1434 may be set based on a time 1416 at which the value of the first sensing signal 1441 changes from “1” to “0,” a fifth target section 1435 may be set based on a time 1417 at which the value of the third sensing signal 1443 changes from “0” to “1,” and a sixth target section 1436 may be set based on a time 1412 at which the value of the second sensing signal 1442 changes from “1” to “0.” For example, the first target section 1431 to the sixth target section 1436 may be set on the rotation timing chart 1410 based on the first sensing signal 1441, the second sensing signal 1442, and the third sensing signal 1443. When the first Hall sensor, the second Hall sensor, and the third Hall sensor are arranged within the motor incorrectly unlike that designed, at least one of the first target section 1431 to the sixth target section 1436 may not match the reference sections.

FIG. 14C illustrates rotation angles of a shaft of a motor for each section, according to an embodiment.

According to an embodiment, the rotation angles for each section may be determined for each of a first target section 1451 to a sixth target section 1456. The first target section 1451 to the sixth target section 1456 may correspond to the first target section 1431 to the sixth target section 1436 described above with reference to FIG. 14B. For example, a first rotation angle 1461 for the first target section 1451 may be determined based on a ratio of a period of the first target section 1451 to the total amount of time. For example, the first rotation angle 1461 for the first target section 1451 may be determined as 55°, a second rotation angle 1462 for a second target section 1452 may be determined as 67°, a third rotation angle 1463 for a third target section 1453 may be determined as 59°, a fourth rotation angle 1464 for a fourth target section 1454 may be determined as 59°, a fifth rotation angle 1465 for a fifth target section 1455 may be determined as 60°, and a sixth rotation angle 1466 for the sixth target section 1456 may be determined as 60°.

According to an embodiment, when at least one of the determined rotation angles for each section is not within a preset range (e.g., a range of A° to B°), at least one of a first Hall sensor, a second Hall sensor, or a third Hall sensor may be determined to be arranged abnormally within the motor.

According to an embodiment, unlike the illustrated embodiment, when at least one of the rotation angles for the first target section 1451 to the sixth target section 1456 is out of a preset normal rotation angle range (e.g., a range of 30° to) 90°, at least one of the first Hall sensor, the second Hall sensor, or the third Hall sensor may be determined to be arranged abnormally within the motor. When at least one of the rotation angles for the first target section 1451 to the sixth target section 1456 is out of the preset normal rotation angle range, the motor may be determined as a defective product.

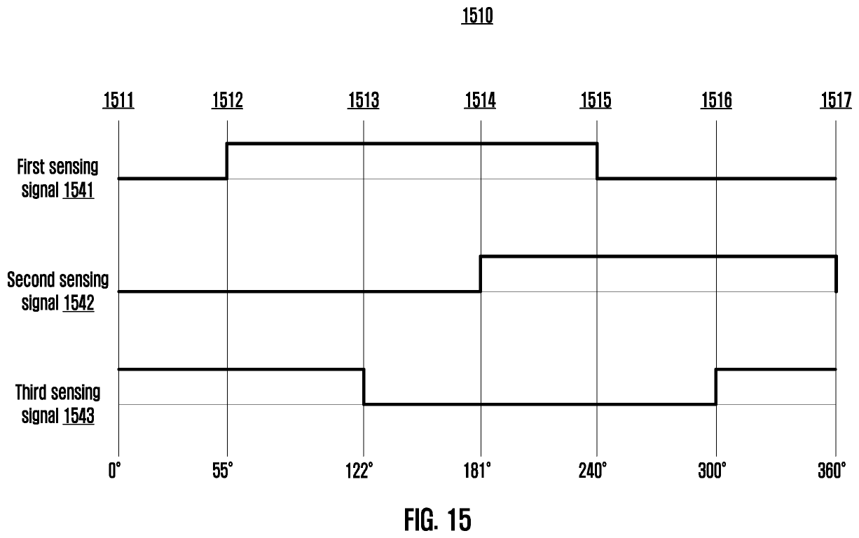

FIG. 15 illustrates a rotation timing chart for a shaft of a motor with calibrated reference sections, according to an embodiment.

According to an embodiment, a driving module (e.g., the driving module 530 of FIG. 5C) may calibrate or adjust sections of a rotation angle, distinguished by a first sensing signal 1541, a second sensing signal 1542, and a third sensing signal 1543, based on the first sensing signal 1541, the second sensing signal 1542, and the third sensing signal 1543. The first sensing signal 1541, the second sensing signal 1542, and the third sensing signal 1543 may be generated by a first Hall sensor (e.g., the first Hall sensor 902a of FIG. 9A), a second Hall sensor (e.g., the second Hall sensor 902b of FIG. 9A) and a third Hall sensor (e.g., the third Hall sensor 902c of FIG. 9A), respectively.

In an embodiment, when a difference between the reference sections and target sections is less than a preset value, the driving module may set target rotation angles for each of the reference sections. For example, a rotation angle of the motor at a time 1512 at which a second reference section starts may be set to an angle of 60° to 55°, a rotation angle of the motor at a time 1513 at which a third reference section starts may be set to an angle of 120° to 122°, and a rotation angle of the motor at a time 1514 at which a fourth reference section starts may be set to an angle of 180° to 181°.

According to an embodiment, even when the difference between the reference sections and the target sections is greater than or equal to the preset value, the driving module may set target rotation angles for each of the reference sections.

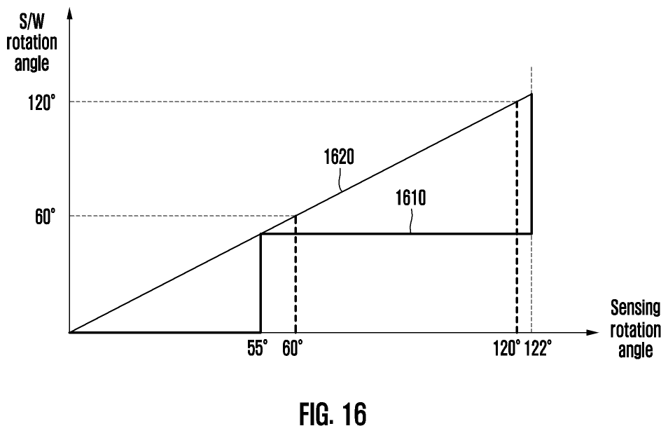

FIG. 16 illustrates a trajectory of a rotation angle of a shaft of a motor determined using calibrated reference sections, according to an embodiment.

When a motor (e.g., the motor 534 of FIG. 5A or the motor 800 of FIG. 8) includes a first Hall sensor (e.g., the first Hall sensor 902a of FIG. 9A), a second Hall sensor (e.g., the second Hall sensor 902b of FIG. 9A), and a third Hall sensor (e.g., the third Hall sensor 902c of FIG. 9A), a sensing rotation angle trajectory 1610 of the shaft (or a camshaft) of the motor may be determined based on a first sensing signal (e.g., the first sensing signal 1441 of FIG. 14B), a second sensing signal (e.g., the second sensing signal 1442 of FIG. 14B), and a third sensing signal (e.g., the third sensing signal 1443 of FIG. 14B) generated by the first Hall sensor, the second Hall sensor, and the third Hall sensor, respectively, while the shaft (or camshaft) of the motor rotates. The sensing rotation angle trajectory 1610 may be a step trajectory. When a change in an operating section from a first reference section to a second reference section is detected based on sensing signals generated by Hall sensors of the motor, the driving module may determine a current rotation angle of the shaft of the motor at a corresponding time as 55°. When a change in the operating section from the second reference section to a third reference section is detected based on sensing signals, the driving module may determine the current rotation angle of the shaft of the motor at a corresponding time as 122°.

The driving module may determine a current rotation angle trajectory 1620 based on the sensing rotation angle trajectory 1610. For example, when a current operating section is the second reference section, the driving module may continuously determine the current rotation angle in the second reference section based on 55° that is a start rotation angle of the second reference section and a rotation speed of the motor before the operating section changes from the second reference section to the third reference section.

When the start rotation angle of the second reference section is still set to 60° because calibration has not been performed, the sensed rotation angle of the shaft of the motor may be determined to be 60° in software even when an actual rotation angle of the shaft of the motor is 55°, which may lead to an unstable control of the motor. Similarly, when a start rotation angle of the third reference section is still set to 120° because calibration has not been performed, the sensed rotation angle of the shaft of the motor may be determined to be 120° in software even when the actual rotation angle of the shaft of the motor is 122°, which may lead to an unstable control of the motor.

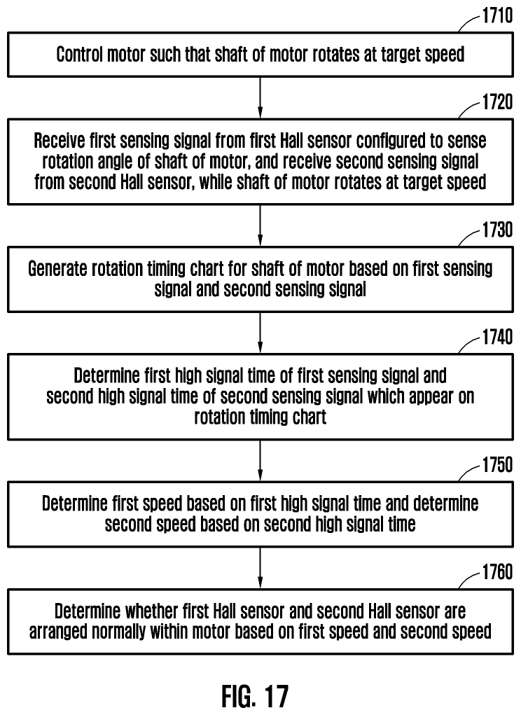

FIG. 17 is a flowchart of a method of determining whether Hall sensors are arranged normally within a motor based on speeds calculated based on sensing signals, according to an embodiment.

According to an embodiment, operations 1710 to 1760 of FIG. 17 may be performed after operation 1130 described above with reference to FIG. 11 is performed.

According to an embodiment, operations 1710 to 1760 may be performed independently of and in parallel with operations 1110 to 1130 described above with reference to FIG. 11.

Operations 1710 to 1760 may be performed by a driving module (e.g., the driving module 530 of FIG. 5C). The driving module may include a processor (e.g., the processor 535 of FIG. 5C) and memory (e.g., the memory 536 of FIG. 5C). The memory may store instructions executable by the processor.

In operation 1710, the driving module may control a motor (e.g., the motor 534 of FIG. 5A or the motor 800 of FIG. 8) such that a shaft (or a camshaft) of the motor may rotate at a target speed. For example, the shaft of the motor may not be connected to a load. The driving module may control the motor such that the shaft of the motor under a no-load state may rotate at the target speed. The description of operation 1710 may be replaced with the description of operation 1110 described above with reference to FIG. 11.

In operation 1720, the driving module may receive a first sensing signal (e.g., the first sensing signal 1541 of FIG. 15) from a first Hall sensor (e.g., the first Hall sensor 902a of FIG. 9A) configured to sense a rotation angle of the shaft of the motor and may receive a second sensing signal (e.g., the second sensing signal 1542 of FIG. 15) from a second Hall sensor (e.g., the second Hall sensor 902b of FIG. 9A), while the shaft of the motor rotates at the target speed. The driving module may further receive a third sensing signal (e.g., the third sensing signal 1543 of FIG. 15) from a third Hall sensor (e.g., the third Hall sensor 902c of FIG. 9A).

In operation 1730, the driving module may generate a rotation timing chart for the shaft of the motor based on the first sensing signal and the second sensing signal generated by the first Hall sensor and the second Hall sensor. For example, the driving module may generate a rotation timing chart further based on a third sensing signal generated by the third Hall sensor.

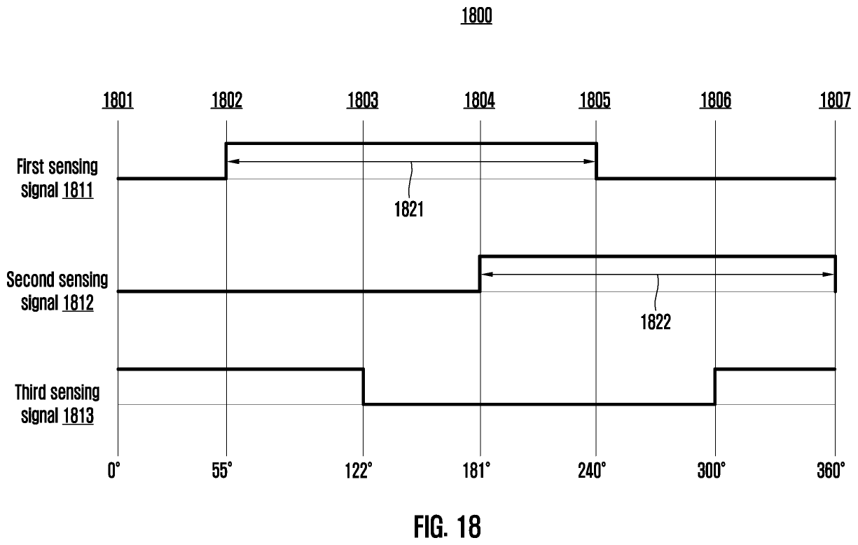

According to an embodiment, the driving module may generate a rotation timing chart of the shaft of the motor with calibrated sections of the rotation angle distinguished by Hall sensors. The generated rotation timing chart is described in detail below with reference to FIG. 18.

In operation 1740, the driving module may determine a first high signal time (or a first low signal time) of the first sensing signal and a second high signal time (or a second low signal time) of the second sensing signal, which appear on the rotation timing chart. The driving module may further determine a third high signal time (or a third low signal time) of the third sensing signal.

In operation 1750, the driving module may determine a first speed based on the first high signal time and may determine a second speed based on the second high signal time. The driving module may further determine a third speed based on the third high signal time. The first speed, the second speed and the third speed that are determined above may be an angular velocity.

In operation 1760, the driving module may determine whether the first Hall sensor and the second Hall sensor are arranged normally within the motor based on the first speed and the second speed. The driving module may further determine whether the first Hall sensor, the second Hall sensor, and the third Hall sensor are arranged normally within the motor based on the first speed, the second speed, and the third speed.

According to an embodiment, the driving module may determine a first error, a second error, and a third error by comparing a target speed with the first speed, the second speed, and the third speed, respectively. When the first Hall sensor, the second Hall sensor, and the third Hall sensor are arranged within the motor correctly as designed, the first error, the second error, and the third error may be zero. For example, when the first error, the second error, and the third error are all greater than or equal to a preset threshold or threshold ratio, the driving module may determine that the first Hall sensor, the second Hall sensor, and the third Hall sensor are arranged normally within the motor. For example, when at least one of the first error, the second error, or the third error is greater than or equal to the preset threshold or threshold ratio, the driving module may determine that at least one of the first Hall sensor, the second Hall sensor, or the third Hall sensor is arranged abnormally within the motor.

In an embodiment, the driving module may determine a first difference by comparing the first speed and the second speed. The driving module may determine a second difference by comparing the first speed and the third speed. The driving module may determine a third difference by comparing the second speed and the third speed. For example, when at least one of calculated differences is greater than or equal to a preset value, the driving module may determine that at least one of the first Hall sensor, the second Hall sensor, or the third Hall sensor is arranged abnormally within the motor.

According to an embodiment, when sections of a rotation angle distinguished by the first Hall sensor, the second Hall sensor, and the third Hall sensor are calibrated, the driving module may determine whether the sections have been calibrated normally, based on the first speed, the second speed, and the third speed. When the sections have been calibrated normally, the first error, the second error, and the third error determined by comparing the target speed to each of the first speed, the second speed, and the third speed may all be zero.

FIG. 18 illustrates a method of calculating a first speed based on a first sensing signal and calculating a second speed based on a second sensing signal, according to an embodiment.

According to an embodiment, a driving module (e.g., the driving module 530 of FIG. 5C) may generate a rotation timing chart 1800 for a shaft of a motor based on a first sensing signal 1811, a second sensing signal 1812, and a third sensing signal 1813 that are generated by a first Hall sensor (e.g., the first Hall sensor 902a of FIG. 9A), a second Hall sensor (e.g., the second Hall sensor 902b of FIG. 9A), and a third Hall sensor (e.g., the third Hall sensor 902c of FIG. 9A), respectively.

According to an embodiment, the driving module may generate the rotation timing chart 1800 by performing operations 1710 to 1730 after calibrating sections of the rotation angle distinguished by the first Hall sensor, the second Hall sensor, and the third Hall sensor.

The driving module may determine times 1801, 1802, 1803, 1804, 1804, 1805, 1806, and 1807 at which at least one of a value of the first sensing signal 1811, a value of the second sensing signal 1812, and a value of the third sensing signal 1813 changes.

The driving module may determine a first high signal period 1821 that is a period during which the first sensing signal 1811 has a high value. For example, the first high signal period 1821 may be a period between a time 1802 and a time 1805. A first rotation angle that changes between the times 1802 and 1805 may be determined to be 185°. The first speed may be determined based on the first high signal period 1821 and the first rotation angle. The first speed may be a first angular velocity.

The driving module may determine a second high signal period 1822 that is a period during which the second sensing signal 1812 has a high value. For example, the second high signal period 1822 may be a period between a time 1804 and a time 1807. A second rotation angle that changes between the times 1804 and 1807 may be determined to be 179°. The second speed may be determined based on the second high signal period 1822 and the second rotation angle. The second speed may be a second angular velocity.

The driving module may determine a third high signal period that is a period in which the third sensing signal 1813 has a high value. For example, the third high signal period may be a sum of a period between a time 1801 and a time 1803 and a period between a time 1806 and a time 1807. A third rotation angle, which is a sum of a rotation angle that changes between the times 1801 and 1803 and a rotation angle that changes between the times 1806 and 1807, may be determined to be 182°. The third speed may be determined based on the third high signal period and the third rotation angle. The third speed may be a third angular velocity.

The driving module may determine whether the first Hall sensor, the second Hall sensor, and the third Hall sensor are arranged normally within the motor based on the first speed, the second speed, and the third speed. For example, the driving module may determine a first error, a second error, and a third error by comparing a target speed to each of the first speed, the second speed, and the third speed. When the first Hall sensor, the second Hall sensor, and the third Hall sensor are arranged within the motor correctly as designed, the first error, the second error, and the third error may be zero.

According to an embodiment, when sections of the rotation angle distinguished by the first Hall sensor, the second Hall sensor, and the third Hall sensor are calibrated, the driving module may determine whether the sections have been calibrated normally, based on the first speed, the second speed, and the third speed. When the sections have been calibrated normally, the first error, the second error, and the third error determined by comparing the target speed to each of the first speed, the second speed, and the third speed may all be zero.

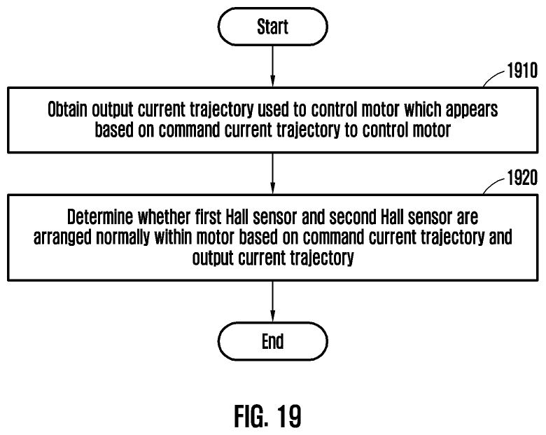

FIG. 19 is a flowchart of a method of determining a state of a motor based on a command current trajectory and an output current trajectory, according to an embodiment.

Operations 1910 and 1920 of FIG. 19 may be performed by a control module (e.g., the control module 130 of FIG. 1 or the control module 510 of FIGS. 5A and 5B) or a driving module (e.g., the driving module 530 of FIG. 5C) of a wearable device. The driving module may include a processor (e.g., the processor 535 of FIG. 5C) and memory (e.g., the memory 536 of FIG. 5C). The memory may store instructions executable by the processor.

According to an embodiment, the driving module may be installed in the wearable device described above with reference to FIG. 1 (e.g., the wearable device 100 of FIG. 1). When the driving module is installed in the wearable device, a control module (e.g., the control module 130 of FIG. 1 or the control module 510 of FIGS. 5A and 5B) of the wearable device may control the driving module. For example, the wearable device may control the driving module to output a torque through a motor (e.g., the motor 534 of FIG. 5A or the motor 800 of FIG. 8). For example, the wearable device may transmit, to the driving module, a command current for outputting a torque. Values of the command current changing over time may be called a “command current trajectory.”

In operation 1910, the control module or the driving module may obtain an output current trajectory used to control the motor which appears based on a command current trajectory to control the motor. For example, the control module or the driver module may obtain the output current trajectory appearing in each of three-phase coils, using a current sensor (e.g., the current sensor 537 of FIG. 5C).

In operation 1920, the control module or the driving module may determine whether a first Hall sensor and a second Hall sensor are arranged normally within the motor based on the command current trajectory and the output current trajectory. For example, the control module or the driving module may determine whether the first Hall sensor, the second Hall sensor, and a third Hall sensor are arranged normally within the motor based on the command current trajectory and the output current trajectory.

According to an embodiment, when a difference between the command current trajectory and the output current trajectory at the same point in time is less than a preset value, the first Hall sensor, the second Hall sensor, and the third Hall sensor may be determined to be arranged normally within the motor.

According to an embodiment, when the first Hall sensor and the second Hall sensor are determined to be arranged abnormally within the motor, the control module may output information on the state of the motor. For example, the control module may inform a user of the state of the motor through at least one of a haptic module, a display, or a sound output module (e.g., the sound output module 550 of FIGS. 5A and 5B) of the wearable device. For example, the control module may transmit the information on the state of the motor to an electronic device (e.g., the electronic device 210 of FIG. 2) connected to the wearable device. The user may identify the state of the motor using the electronic device.

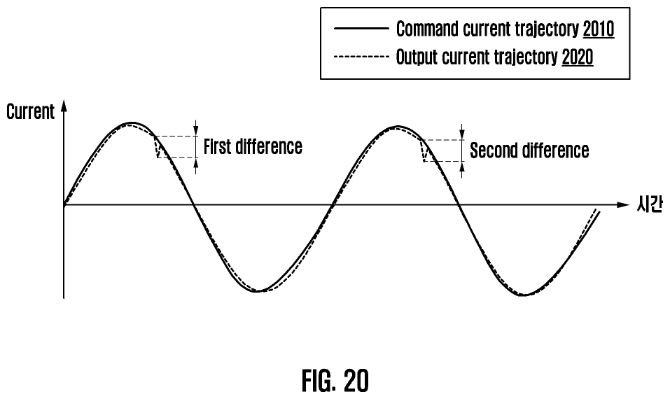

FIG. 20 illustrates a command current trajectory and an output current trajectory, according to an embodiment.

A control module (e.g., the control module 130 of FIG. 1 or the control module 510 of FIGS. 5A and 5B) or a driving module (e.g., the driving module 530 of FIG. 5C) of a wearable device may determine a difference between a command current trajectory 2010 transmitted by the control module of the wearable device to the driving module and an output current trajectory 2020 sensed by a current sensor (e.g., the current sensor 537 of FIG. 5C).

According to an embodiment, when a plurality of Hall sensors (e.g., the first Hall sensor 902a, the second Hall sensor 902b, and the third Hall sensor 902c of FIG. 9A) is arranged normally within a motor (e.g., the motor 534 of FIG. 5A or the motor 800 of FIG. 8), the difference between the command current trajectory 2010 and the output current trajectory 2020 may not be significant. For example, when a first difference between the command current trajectory 2010 and the output current trajectory 2020 is greater than or equal to a preset value, the plurality of Hall sensors may be determined to be arranged abnormally within the motor. When the plurality of Hall sensors is arranged abnormally within the motor, a difference (e.g., a second difference) between the command current trajectory 2010 and the output current trajectory 2020 may continue to occur in the same phase of the output current trajectory 2020.

According to an embodiment, when sections of a rotation angle distinguished by the plurality of Hall sensors are calibrated normally, the difference between the command current trajectory 2010 and the output current trajectory 2020 may not be significant. For example, when the first difference between the command current trajectory 2010 and the output current trajectory 2020 is greater than or equal to the preset value, it may be determined that the sections have not been calibrated normally. When the sections have not been calibrated normally, the difference (e.g., the second difference) between the command current trajectory 2010 and the output current trajectory 2020 may continue to occur in the same phase of the output current trajectory 2020.

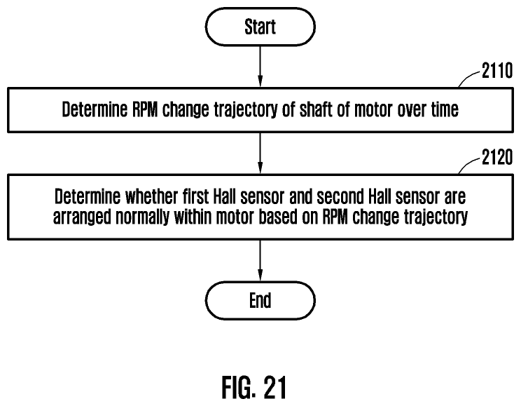

FIG. 21 is a flowchart of a method of determining a state of a motor based on a rotations per minute (RPM) change trajectory of a shaft of the motor, according to an embodiment.

Operations 2110 and 2120 of FIG. 21 may be performed by a control module (e.g., the control module 130 of FIG. 1 or the control module 510 of FIGS. 5A and 5B) or a driving module (e.g., the driving module 530 of FIG. 5C) of a wearable device. The driving module may include a processor (e.g., the processor 535 of FIG. 5C) and memory (e.g., the memory 536 of FIG. 5C). The memory may store instructions executable by the processor.

According to an embodiment, operations 2110 and 2120 may be performed independently of and in parallel with operations 1910 and 1920 described above with reference to FIG. 19.

According to an embodiment, operations 2110 and 2120 may be performed after operation 1920 described above with reference to FIG. 19 is performed.

According to an embodiment, the driving module may be installed in the wearable device described above with reference to FIG. 1 (e.g., the wearable device 100 of FIG. 1). When the driving module is installed in the wearable device, a control module (e.g., the control module 130 of FIG. 1 or the control module 510 of FIGS. 5A and 5B) of the wearable device may control the driving module.

Each embodiment herein may be used in combination with any other embodiment(s) described herein.

In operation 2110, the control module or the driving module may determine an RPM change trajectory of a shaft of a motor (e.g., the motor 534 of FIG. 5A or the motor 800 of FIG. 8) over time.

According to an embodiment, the wearable device may control the driving module to output torque through the motor. For example, the wearable device may transmit, to the driving module, a command current for outputting a torque. The driving module may control the motor based on the command current. An RPM of the shaft of the motor may change based on the command current. Values of the RPM changing over time may be named as an “RPM change trajectory.”

In operation 2120, the control module or the driving module may determine whether a first Hall sensor (e.g., the first Hall sensor 902a of FIG. 9A) and a second Hall sensor (e.g., the second Hall sensor 902b of FIG. 9A) are arranged normally within the motor based on the RPM change trajectory. For example, the control module or the driving module may determine whether the first Hall sensor, the second Hall sensor, and a third Hall sensor (e.g., the third Hall sensor 902c of FIG. 9A) are arranged normally within the motor based on the RPM change trajectory. For example, for the RPM change trajectory, when the RPM changes by a first difference or greater within a preset amount of time, the first Hall sensor and the second Hall sensor may be determined to be arranged abnormally within the motor.

According to an embodiment, when the first Hall sensor and the second Hall sensor are determined to be arranged abnormally within the motor, the control module may output information on the state of the motor. For example, the control module may inform a user of the state of the motor through at least one of a haptic module, a display, or a sound output module (e.g., the sound output module 550 of FIGS. 5A and 5B) of the wearable device. For example, the control module may transmit the information on the state of the motor to an electronic device (e.g., the electronic device 210 of FIG. 2) connected to the wearable device. The user may identify the state of the motor using the electronic device.

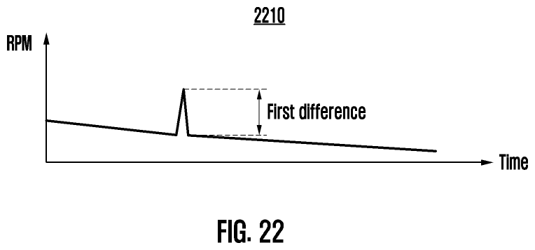

FIG. 22 illustrates an RPM change trajectory of a shaft of a motor, according to an embodiment.

A control module (e.g., the control module 130 of FIG. 1 or the control module 510 of FIGS. 5A and 5B) or a driving module (e.g., the driving module 530 of FIG. 5C) of a wearable device may determine whether the RPM has changed by a first difference or greater within a preset amount of time for an RPM change trajectory 2210.

According to an embodiment, when the RPM has changed by the first difference or greater within the preset amount of time, the control module or the driving module may determine that a first Hall sensor (e.g., the first Hall sensor 902a of FIG. 9A) and a second Hall sensor (e.g., the second Hall sensor 902b of FIG. 9A) are arranged abnormally within the motor.

According to an embodiment, when the RPM has changed by the first difference or greater within the preset amount of time, the control module or the driving module may determine that sections of a rotation angle distinguished by a plurality of Hall sensors including the first Hall sensor and the second Hall sensor are not calibrated normally.

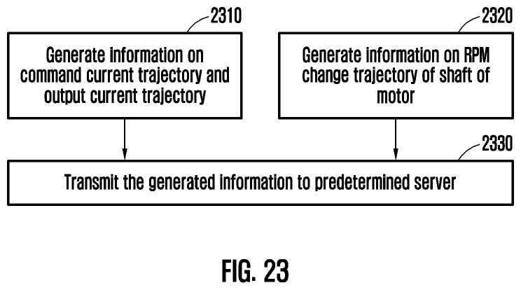

FIG. 23 is a flowchart of a method of transmitting information about a motor to a preset server, according to an embodiment.

Operations 2310, 2320, and 2330 of FIG. 23 may be performed by a control module (e.g., the control module 130 of FIG. 1 or the control module 510 of FIGS. 5A and 5B) of a wearable device. For example, operation 2310 may be performed after operation 1920 described above with reference to FIG. 19 is performed. For example, operation 2320 may be performed after operation 2120 described above with reference to FIG. 21 is performed.

In operation 2310, the control module may generate information on a command current trajectory (e.g., the command current trajectory 2010 of FIG. 20) and an output current trajectory (e.g., the output current trajectory 2020 of FIG. 20). The generated information may be a log including a first difference between the command current trajectory and the output current trajectory.

In operation 2320, the control module may generate information on an RPM change trajectory of a shaft of the motor (e.g., the RPM change trajectory 2210 of FIG. 22). The generated information may be a log including information on a change in the RPM by the first difference or greater within the preset amount of time.

In operation 2330, the control module may transmit the generated information to a predetermined server. For example, the information transmitted to the server may be used to diagnose the wearable device.

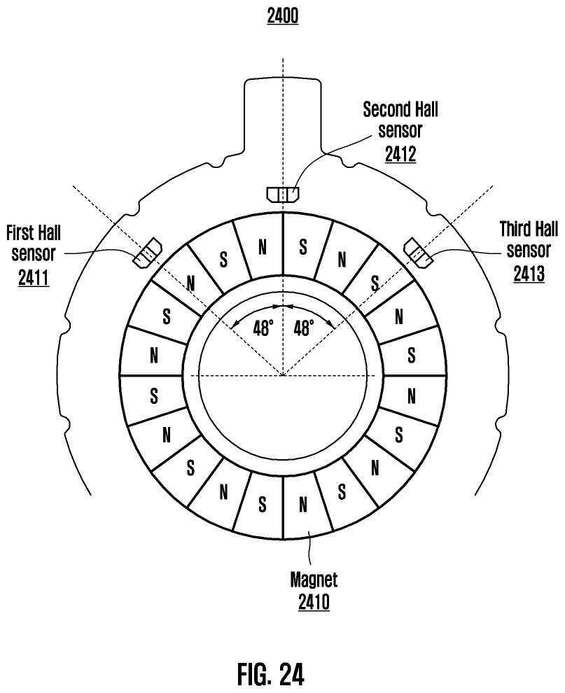

FIG. 24 illustrates a magnet and a plurality of Hall sensors arranged within a motor, according to an embodiment.

According to an embodiment, a magnet (e.g., the magnet 901 of FIG. 9A), a first Hall sensor (e.g., the first Hall sensor 902a of FIG. 9A), a second Hall sensor (e.g., the second Hall sensor 902b of FIG. 9A), and a third Hall sensor (e.g., the third Hall sensor 902c of FIG. 9A) included in a motor (e.g., the motor 534 of FIG. 5A or the motor 800 of FIG. 8) have been described with reference to FIG. 9A, however, embodiments are not limited thereto. From the perspective of control of the motor, a structure of a magnet and a plurality of Hall sensors having the same measurement results as those of the magnet 901 and the plurality of Hall sensors of FIG. 9A may be provided.

According to an embodiment, a motor 2400 may include a magnet 2410 that rotates together with a shaft of the motor 2400 as the shaft of the motor 2400 rotates, a first Hall sensor 2411, a second Hall sensor 2412, and a third Hall sensor 2413. For example, the magnet 2410 may be configured such that N poles and S poles may be alternately and evenly arranged. Ten N-pole magnets and ten S-pole magnets may be arranged in the magnet 2410. A pair of an N-pole magnet and an S-pole magnet may have a rotation angle of 36° from the center of the magnet 2410. From the perspective of control of the motor 2400, a 36-degree rotation of the magnet 2410 may correspond to a 360-degree rotation of a magnet (e.g., the magnet 901 of FIG. 9A) including one N-pole magnet and one S-pole magnet.

The first Hall sensor 2411 and the second Hall sensor 2412 may be arranged to have a rotation angle of 48° from the center of the magnet 2410. When a pair of an N-pole magnet and an S-pole magnet has a rotation angle of 36° from the center of the magnet 2410, a rotation angle of 48° (or 12°,) 84° between the first Hall sensor 2411 and the second Hall sensor 2412 may correspond to a rotation angle of 120° between a first Hall sensor (e.g., the first Hall sensor 902a of FIG. 9A) and a second Hall sensor (e.g., the second Hall sensor 902b of FIG. 9A) arranged in a magnet (e.g., the magnet 901 of FIG. 9A) including one N-pole magnet and one S-pole magnet, from the perspective of the control of the motor 2400.

Similarly, the second Hall sensor 2412 and the third Hall sensor 2413 may be arranged to have a rotation angle of 48° from the center of the magnet 2410. When a pair of an N-pole magnet and an S-pole magnet has a rotation angle of 36° from the center of the magnet 2410, a rotation angle of 48° (or, 12°,) 84° between the second Hall sensor 2412 and the third Hall sensor 2413 may correspond to a rotation angle of 120° between a second Hall sensor (e.g., the second Hall sensor 902b of FIG. 9A) and a third Hall sensor (e.g., the third Hall sensor 902c of FIG. 9A) arranged in a magnet (e.g., the magnet 901 of FIG. 9A) including one N-pole magnet and one S-pole magnet, from the perspective of the control of the motor 2400.

According to an embodiment, a driving module 35, 45, 530 may include at least one processor 535, and memory 536 storing instructions executable by the at least one processor 535, wherein the instructions, when executed by the at least one processor 535, cause the driving module 35, 45, 530 to at least control a motor 534, 800, 2400 of the driving module 35, 45, 530 such that a shaft of the motor 534, 800, 2400 rotates at a target speed, receive a first sensing signal from a first Hall sensor 902a, 2411 and receive a second sensing signal from a second Hall sensor 902b, 2412, while the shaft of the motor 534, 800, 2400 rotates at the target speed, the first Hall sensor 902a, 2411 being configured to sense a rotation angle of the shaft of the motor 534, 800, 2400, and determine whether the first Hall sensor 902a, 2411 and the second Hall sensor 902b, 2412 are arranged normally within the motor 534, 800, 2400, based on the first sensing signal and the second sensing signal.

According to an embodiment, the instructions, when executed by the at least one processor 535, may cause the driving module 35, 45, 530 to at least control the motor 534, 800, 2400 such that the shaft of the motor 534, 800, 2400 rotates at the target speed, by controlling a motor driver circuit 532, 810, connected, directly or indirectly, to the motor 534, 800, 2400, using an FOC.

According to an embodiment, the instructions, when executed by the at least one processor 535, may cause the driving module 35, 45, 530 to at least generate a rotation timing chart for a shaft of the motor 534, 800, 2400 based on the first sensing signal and the second sensing signal, set reference sections for each of preset reference rotation angles on the rotation timing chart based on a total amount of time of the rotation timing chart, and determine whether the first Hall sensor and the second Hall sensor 902b, 2412 are arranged normally within the motor 534, 800, 2400, based on the first sensing signal, the second sensing signal, and the reference sections.

According to an embodiment, the instructions, when executed by the at least one processor 535, may cause the driving module 35, 45, 530 to at least set target sections based on the first sensing signal and the second sensing signal, and determine that at least one of the first Hall sensor or the second Hall sensor 902b, 2412 is arranged abnormally within the motor 534, 800, 2400, when a difference between the reference sections and the target sections is greater than or equal to a preset value.

According to an embodiment, the instructions, when executed by the at least one processor 535, may cause the driving module 35, 45, 530 to at least set target sections based on the first sensing signal and the second sensing signal, and determine that the first Hall sensor and the second Hall sensor 902b, 2412 are arranged normally within the motor 534, 800, 2400, when a difference between the reference sections and the target sections is less than a preset value.

According to an embodiment, the instructions, when executed by the at least one processor 535, may cause the driving module 35, 45, 530 to at least set target rotation angles for each of the reference sections, when the difference between the reference sections and the target sections is less than the preset value.

According to an embodiment, the target rotation angles set for each of the reference sections may be used to determine a current rotation angle of the shaft of the motor 534, 800, 2400.

According to an embodiment, the instructions, when executed by the at least one processor 535, may cause the driving module 35, 45, 530 to at least generate a rotation timing chart for the shaft of the motor 534, 800, 2400 based on the first sensing signal and the second sensing signal, determine a first high signal time of the first sensing signal and a second high signal time of the second sensing signal, which appear on the rotation timing chart, determine a first speed based on the first high signal time, determine a second speed based on the second high signal time, and determine whether the first Hall sensor and the second Hall sensor 902b, 2412 are arranged normally within the motor 534, 800, 2400, based on the first speed and the second speed.

According to an embodiment, the instructions, when executed by the at least one processor 535, may cause the driving module 35, 45, 530 to at least determine whether the first Hall sensor is arranged normally within the motor 534, 800, 2400 based on a first error between the target speed and the first speed.

According to an embodiment, the instructions, when executed by the at least one processor 535, may cause the driving module 35, 45, 530 to at least determine whether the first Hall sensor and the second Hall sensor 902b, 2412 are arranged normally within the motor 534, 800, 2400, based on a difference between the first speed and the second speed.

According to an embodiment, a method of determining a state of a motor 534, 800, 2400 performed by a driving module 35, 45, 530 may include controlling the motor 534, 800, 2400 of the driving module 35, 45, 530 such that a shaft of the motor 534, 800, 2400 rotates at a target speed, receiving a first sensing signal from a first Hall sensor and receiving a second sensing signal from a second Hall sensor 902b, 2412, while the shaft of the motor 534, 800, 2400 rotates at the target speed, the first Hall sensor being configured to sense a rotation angle of the shaft of the motor 534, 800, 2400, and determining whether the first Hall sensor and the second Hall sensor 902b, 2412 are arranged normally within the motor 534, 800, 2400, based on the first sensing signal and the second sensing signal.

According to an embodiment, a wearable device 100 may include a base body 80 configured to be disposed on, directly or indirectly, an area of a lower back of a user 110 when the wearable device 100 is worn on the body of the user 110, a waist support frame 20 and a leg support frame 50, 55, 810 configured to support at least a part of the body of the user 110, a thigh fastening portion 1, 2 configured to fix the leg support frame 50, 55, 810 to a thigh of the user 110, an IMU 135 disposed within the base body, a driving module 35, 45, 530 configured to generate a torque applied to a leg of the user 110, wherein the driving module 35, 45, 530 is disposed between the waist support frame 20 and the leg support frame 50, 55, 810, and may include a processor 535, memory 536 storing instructions executable by the processor 535, a motor 534, 800, 2400, and a first Hall sensor 902a, 2411 and a second Hall sensor 902b, 2412 configured to sense a rotation angle of a shaft of the motor 534, 800, 2400, and a control module 130, 510 configured to control the wearable device 100.

According to an embodiment, the instructions, when executed by the processor 535, may cause the driving module 35, 45, 530 to at least obtain an output current trajectory used to control the motor 534, 800, 2400 which appears based on a command current trajectory used to control the motor 534, 800, 2400, and determine whether the first Hall sensor 902a, 2411 and the second Hall sensor 902b, 2412 are arranged normally within the motor 534, 800, 2400, based on the command current trajectory and the output current trajectory.

According to an embodiment, the instructions, when executed by the processor 535, may cause the driving module 35, 45, 530 to at least determine an RPM variation trajectory of the shaft of the motor 534, 800, 2400 over time, and determine whether the first Hall sensor 902a, 2411 and the second Hall sensor 902b, 2412 are arranged normally within the motor 534, 800, 2400, based on the RPM change trajectory.

According to an embodiment, the instructions, when executed by the processor 535, may cause the driving module 35, 45, 530 to at least control the motor 534, 800, 2400 such that the shaft of the motor 534, 800, 2400 rotates at a target speed, receive a first sensing signal from the first Hall sensor 902a, 2411 and receive a second sensing signal from the second Hall sensor 902b, 2412, while the shaft of the motor 534, 800, 2400 rotates at the target speed, and determine whether the first Hall sensor 902a, 2411 and the second Hall sensor 902b, 2412 are arranged normally within the motor 534, 800, 2400, based on the first sensing signal and the second sensing signal.

According to an embodiment, the instructions, when executed by the processor 535, may cause the driving module 35, 45, 530 to at least control the motor 534, 800, 2400 such that the shaft of the motor 534, 800, 2400 rotates at the target speed, by controlling a motor driver circuit 532, 810, connected, directly or indirectly, to the motor 534, 800, 2400, using an FOC.

According to an embodiment, the instructions, when executed by the processor 535, may cause the driving module 35, 45, 530 to at least generate a rotation timing chart for the shaft of the motor 534, 800, 2400 based on the first sensing signal and the second sensing signal, set reference sections for each of preset reference rotation angles on the rotation timing chart based on a total amount of time of the rotation timing chart, and determine whether the first Hall sensor 902a, 2411 and the second Hall sensor 902b, 2412 are arranged normally within the motor 534, 800, 2400, based on the first sensing signal, the second sensing signal, and the reference sections. “Based on” as used herein covers based at least on.

According to an embodiment, the instructions, when executed by the processor 535, may cause the driving module 35, 45, 530 to at least set target sections based on the first sensing signal and the second sensing signal, and determine that the first Hall sensor 902a, 2411 and the second Hall sensor 902b, 2412 are arranged normally within the motor 534, 800, 2400, when a difference between the reference sections and the target sections is less than a preset value.

According to an embodiment, the instructions, when executed by the processor 535, may cause the driving module 35, 45, 530 to at least set target rotation angles for each of the target sections when the difference between the reference sections and the target sections is less than the preset value.

According to an embodiment, the instructions, when executed by the processor 535, may cause the driving module 35, 45, 530 to at least transmit information on the command current trajectory and the output current trajectory to a predetermined server.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, a field-programmable gate array (FPGA), a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is singular; however, one of ordinary skill in the art will appreciate that a processing device may include multiple processing elements and multiple types of processing elements. For example, the processing device may include a plurality of processors, or a single processor and a single controller. In addition, different processing configurations are possible, such as parallel processors.

Software may include a computer program, a piece of code, an instruction, or one or more combinations thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the embodiments described herein may be recorded in non-transitory computer-readable media including program instructions to implement various operations of the embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs and/or DVDs; magneto-optical media such as optical discs; and hardware devices that are specially configured to store and perform program instructions, such as read-only memory (ROM), RAM, flash memory, and the like. Examples of program instructions include both machine code, such as produced by a compiler, and files containing higher-level code that may be executed by the computer using an interpreter.

The above-described hardware devices may be configured to act as one or more software modules in order to perform the operations of the above-described examples, or vice versa.

As described above, although the embodiments have been described with reference to the limited drawings, one of ordinary skill in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents. While the disclosure has been illustrated and described with reference to various embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

Therefore, other implementations, other embodiments, and equivalents to the claims are also within the scope of the following claims.

What is claimed is:

1. A driving module comprising:
at least one processor comprising processing circuitry; and
memory storing instructions executable by the at least one processor,
wherein the instructions, when executed by the at least one processor individually and/or collectively, are configured to cause the driving module, comprising a motor and/or a motor driver circuit, to at least:
control the motor of the driving module such that the shaft of the motor rotates at a target speed;
receive a first sensing signal from a first Hall sensor and receive a second sensing signal from a second Hall sensor, while the shaft of the motor rotates at the target speed, the first Hall sensor being configured to sense a rotation angle of the shaft of the motor; and
determine whether the first Hall sensor and the second Hall sensor are arranged normally within the motor, based on the first sensing signal and the second sensing signal.

2. The driving module of claim 1, wherein the instructions, when executed by the at least one processor, are configured to cause the driving module to at least:
control the motor such that the shaft of the motor rotates at the target speed, by controlling the motor driver circuit, connected to the motor, using a field-oriented control (FOC).

3. The driving module of claim 1, wherein the instructions, when executed by the at least one processor, are configured to cause the driving module to at least:
generate a rotation timing chart for the shaft of the motor based on the first sensing signal and the second sensing signal;
set reference sections for each of preset reference rotation angles on the rotation timing chart, based on a total amount of time of the rotation timing chart; and
determine whether the first Hall sensor and the second Hall sensor are arranged normally within the motor, based on the first sensing signal, the second sensing signal, and the reference sections.

4. The driving module of claim 3, wherein the instructions, when executed by the at least one processor, are configured to cause the driving module to at least:
set target sections based on the first sensing signal and the second sensing signal; and
determine that at least one of the first Hall sensor or the second Hall sensor is arranged abnormally within the motor, when a difference between the reference sections and the target sections is greater than or equal to a preset value.

5. The driving module of claim 4, wherein the instructions, when executed by the at least one processor, are configured to cause the driving module to at least:
set target sections based on the first sensing signal and the second sensing signal; and
determine that the first Hall sensor and the second Hall sensor are arranged normally within the motor, when a difference between the reference sections and the target sections is less than a preset value.

6. The driving module of claim 4, wherein the instructions, when executed by the at least one processor, are configured to cause the driving module to at least:
set target rotation angles for each of the reference sections, when a difference between the reference sections and the target sections is less than a preset value.

7. The driving module of claim 6, wherein the target rotation angles set for each of the reference sections are used to determine a current rotation angle of the shaft of the motor.

8. The driving module of claim 1, wherein the instructions, when executed by the at least one processor, are configured to cause the driving module to at least:
generate a rotation timing chart for the shaft of the motor based on the first sensing signal and the second sensing signal;
determine a first high signal time of the first sensing signal and a second high signal time of the second sensing signal, which appear on the rotation timing chart;
determine a first speed based on the first high signal time, and determine a second speed based on the second high signal time; and
determine whether the first Hall sensor and the second Hall sensor are arranged normally within the motor, based on the first speed and the second speed.

9. The driving module of claim 8, wherein the instructions, when executed by the at least one processor, are configured to cause the driving module to at least:
determine whether the first Hall sensor is arranged normally within the motor based on a first error between the target speed and the first speed.

10. The driving module of claim 8, wherein the instructions, when executed by the at least one processor, are configured to cause the driving module to at least:
determine whether the first Hall sensor and the second Hall sensor are arranged normally within the motor, based on a difference between the first speed and the second speed.

11. A method of determining a state of a motor of a wearable device, the method being performed by a driving module comprising a motor and/or circuitry, the method comprising:
controlling the motor of the driving module such that a shaft of the motor rotates at a target speed;
receiving a first sensing signal from a first Hall sensor and receiving a second sensing signal from a second Hall sensor, while the shaft of the motor rotates at the target speed, the first Hall sensor being configured to sense a rotation angle of the shaft of the motor; and
determining whether the first Hall sensor and the second Hall sensor are arranged normally within the motor, based on the first sensing signal and the second sensing signal.

12. A non-transitory computer-readable storage medium storing instructions that, when executed by at least one processor comprising processing circuitry, cause the at least one processor to individually and/or collectively perform the method of claim 11.

13. A wearable device comprising:
a base body configured to be disposed on an area of a lower back of a user when the wearable device is worn on a body of the user;
a waist support frame and a leg support frame configured to support at least a part of the body of the user;
a thigh fastening portion, comprising a support, configured to operatively associate the leg support frame to a thigh of the user;
an inertial measurement unit (IMU), comprising a sensor and/or circuitry, disposed within the base body;
a driving module configured to generate a torque applied to a leg of the user, the driving module being disposed between at least the waist support frame and the leg support frame, and comprising at least one processor comprising processing circuitry, memory storing instructions executable by the at least one processor, a motor, and a first Hall sensor and a second Hall sensor configured to sense a rotation angle of a shaft of the motor; and
a control module, comprising processing circuitry, configured to control the wearable device,
wherein the driving module is configured to at least:
obtain an output current trajectory used to control the motor based on a command current trajectory used to control the motor; and
determine whether the first Hall sensor and the second Hall sensor are arranged normally within the motor, based on the command current trajectory and the output current trajectory.

14. The wearable device of claim 13, wherein the driving module is configured to at least:
determine a rotations per minute (RPM) change trajectory of the shaft of the motor over time; and
determine whether the first Hall sensor and the second Hall sensor are arranged normally within the motor, based on the RPM change trajectory.

15. The wearable device of claim 13, wherein the driving module is configured to at least:
control the motor such that the shaft of the motor rotates at a target speed;
receive a first sensing signal from the first Hall sensor and receive a second sensing signal from the second Hall sensor, while the shaft of the motor rotates at the target speed; and
determine whether the first Hall sensor and the second Hall sensor are arranged normally within the motor, based on the first sensing signal and the second sensing signal.

16. The wearable device of claim 15, wherein the driving module is configured to at least:
control the motor such that the shaft of the motor rotates at the target speed, by controlling a motor driver circuit of the driving module, connected to the motor, using a field-oriented control (FOC).

17. The wearable device of claim 15, wherein the driving module is configured to at least:
generate a rotation timing chart for the shaft of the motor based on the first sensing signal and the second sensing signal;
set reference sections for each of preset reference rotation angles on the rotation timing chart, based on a total amount of time of the rotation timing chart; and
determine whether the first Hall sensor and the second Hall sensor are arranged normally within the motor, based on the first sensing signal, the second sensing signal, and the reference sections.

18. The wearable device of claim 15, wherein the driving module is configured to at least:
set target sections based on the first sensing signal and the second sensing signal; and
determine that the first Hall sensor and the second Hall sensor are arranged normally within the motor, when a difference between the reference sections and the target sections is less than a preset value.

19. The wearable device of claim 18, wherein the driving module is configured to at least:
set target rotation angles for each of the target sections, when the difference between the reference sections and the target sections is less than the preset value.

20. The wearable device of claim 13, wherein the driving module is configured to at least:
transmit information on the command current trajectory and the output current trajectory to a predetermined server.
